(19) United States
(12) Patent Application Publication
(10) Pub. No.: US 2023/0354577 A1
(43) Pub. Date: Nov. 2, 2023

(54) DYNAMIC FLASH MEMORY (DFM) WITH TRI-GATE FOR HIGH EFFICIENCY OPERATION

(71) Applicant: Yangtze Memory Technologies Co., Ltd., Wuhan (CN)

(72) Inventors: Dongxue ZHAO, Wuhan (CN); Tao Yang, Wuhan (CN); Yuancheng Yang, Wuhan (CN); Lei Liu, Wuhan (CN); Di Wang, Wuhan (CN); Kun Zhang, Wuhan (CN); Wenxi Zhou, Wuhan (CN); Zhiliang Xia, Wuhan (CN); Zongliang Huo, Wuhan (CN)

(73) Assignee: Yangtze Memory Technologies Co., Ltd., Wuhan (CN)

(21) Appl. No.: 17/731,520

(22) Filed: Apr. 28, 2022

(51) Int. Cl. H01L 27/108

(52) U.S. Cl. CPC H01L 27/10802

(57) ABSTRACT

A three-dimensional (3D) memory device includes a memory cell, a top contact coupled to the memory cell, and a bottom contact coupled to the memory cell. The memory cell can include a pillar, an insulating layer surrounding the pillar, a first gate contact coupled to a word line, a second gate contact coupled to a plate line, and a third gate contact configured to control electrical charge conduction between the first gate contact and the second gate contact. The 3D memory device can utilize dynamic flash memory (DFM), increase storage efficiency, provide tri-gate control, provide different programming options, increase read, program, and erase operation rates, decrease leakage current, increase retention time, and decrease refresh rates.

### BACKGROUND

### FIELD

The present disclosure relates to dynamic flash memory (DFM) apparatuses, systems, and methods, for example, tri-gate DFM apparatuses, systems, and methods to increase storage efficiency in a three-dimensional (3D) memory device.

### BACKGROUND

Dynamic random-access memory (DRAM) is a volatile memory that uses charge stored on a capacitor to represent information. DRAM stores each bit in a memory cell that includes a transistor and a capacitor (e.g., 1T1C). Charge levels greater than a certain threshold can represent a first logic level (e.g., 1 state) and charge levels less than another threshold amount can represent a second logic level (e.g., 0 state). Leakage currents and various parasitic effects limit the length of time a capacitor can hold charge and regular refresh cycles are needed. DRAM retention times can be as low as 32 ms during high temperature operations (e.g., above 85° C.) and can require refresh rates of about 31 Hz.

Flash memory (flash) is a non-volatile memory that uses charge stored on a floating gate to represent information. Flash stores each bit in a memory cell that includes a transistor with a floating gate. The amount of charge on the floating gate will determine whether the transistor will conduct when a fixed set of read bias conditions are applied. Flash can retain charge for a long period of time (e.g., about 10 years at 85° C.) since the floating gate is completely surrounded by insulators. Further, the act of reading the data can be performed non-destructively without loss of the information. In addition, flash can quickly erase entire blocks or pages of data simultaneously (e.g., NAND flash).

Current 1T1C DRAM is approaching a process limit. The manufacturing of 1T1C DRAM devices with small-node capacitors to retain charge is becoming more difficult due to increased current leakage, increased power consumption, degraded operating voltage margins, and decreased retention times. Further, current single transistor (1T) capacitor-free DRAM (e.g., ZRAM, TTRAM, ARAM, etc.) devices need further improvement and optimization for manufacturable integration and operation solutions.

### SUMMARY

Accordingly, there is a need to, e.g., provide a capacitor-free dynamic random-access memory device to increase memory storage efficiency. Further, there is a need to provide tri-gate control with different programming options (e.g., impact ionization, gate-induced drain leakage (GIDL), gate-induced source leakage (GISL)). Further, there is a need to increase read, program, and erase operation rates. Further, there is a need to decrease leakage current, decrease junction current, and decrease power consumption. Further, there is a need to increase charge retention times and decrease refresh rates.

In some aspects, a three-dimensional (3D) memory device includes a memory cell, a top contact coupled to the memory cell, and a bottom contact coupled to the memory cell. In some aspects, the 3D memory device can increase memory storage efficiency, provide tri-gate control, provide different programming options (e.g., impact ionization, GIDL, GISL), increase read, program, and erase operation rates, decrease leakage current, decrease junction current, decrease power consumption, increase charge retention times, and decrease refresh rates.

In some aspects, the memory cell can include a pillar, an insulating layer, a first gate contact, a second gate contact, and a third gate contact. In some aspects, the pillar can be configured to store an electrical charge. In some aspects, the insulating layer can surround the pillar. In some aspects, the first gate contact can surround a first portion of the insulating layer. In some aspects, the first gate contact can be coupled to a word line configured to address and non-destructively read the pillar. In some aspects, the second gate contact can surround a second portion of the insulating layer. In some aspects, the second gate contact can be coupled to a plate line configured to program the pillar. In some aspects, the third gate contact can surround a third portion of the insulating layer. In some aspects, the third gate contact can be configured to control electrical charge conduction between the first gate contact and the second gate contact.

In some aspects, the top contact can be coupled to a bit line configured to flow electrical charge through and/or away from the memory cell. In some aspects, the bottom contact can be coupled to a source line configured to flow electrical charge through and/or away from the memory cell. In some aspects, different voltage combinations can be applied to the bit line, the word line, the plate line, the third gate contact, and the source line to perform read (e.g., non-destructively), program (e.g., 1 state), and erase (e.g., 0 state) operations on the 3D memory device.

In some aspects, the pillar can be a monolithic vertical pillar. In some aspects, the monolithic vertical pillar can be a single semiconductor material (e.g., silicon, doped silicon, monocrystalline silicon, etc.). In some aspects, the monolithic vertical pillar can decrease defect concentrations, increase charge conduction, decrease leakage current, and increase manufacturing efficiency.

In some aspects, the insulating layer can be a monolithic insulating layer. In some aspects, the monolithic insulating layer can be a single dielectric material (e.g., high-k dielectric, oxide, nitride, silicon oxide, silicon nitride, glass, SOG, etc.). In some aspects, the monolithic insulating layer can decrease defect concentrations, increase gate capacitance, decrease leakage current, and increase manufacturing efficiency.

In some aspects, the third gate contact can be configured to increase a program rate of the pillar. In some aspects, the third gate contact can increase the flow of electrical charge to the pillar of the memory cell.

In some aspects, the 3D memory device can be configured for impact ionization programming, GIDL programming, or both.

In some aspects, the third gate contact can be coupled to a dummy line. In some aspects, for impact ionization programming, the dummy line can be configured to increase a charge flow from the first gate contact to the second gate contact. In some aspects, for impact ionization programming, the dummy line can apply a voltage to increase a charge flow from the first gate contact to the second gate contact. In some aspects, the charge flow can have a charge density greater than about 1×10¹⁷ cm⁻³.

In some aspects, the third gate contact can be coupled to a top select gate (TSG) line or a bottom select gate (BSG) line. In some aspects, for GIDL programming, the TSG line or the BSG line can be configured to create a charge barrier between the first gate contact and the second gate contact to selectively program the pillar. In some aspects, for GIDL programming, the TSG line or the BSG line can apply a voltage to create a charge barrier between the first gate contact and the second gate contact to selectively program the pillar. In some aspects, the charge barrier can have a charge density of no greater than 1×10¹⁷ cm⁻³.

In some aspects, the third gate contact can be between the first gate contact and the second gate contact.

In some aspects, in a first configuration (e.g., 1 state), the top contact can have a HIGH level voltage (e.g., about 0.8 V), the first gate contact can have a HIGH level voltage (e.g., about 1.5 V), the second gate contact can have a HIGH level voltage (e.g., about 0.8 V), the third gate contact can have a HIGH level voltage (e.g., about 1 V), the bottom contact can have a LOW level voltage (e.g., about 0 V or GND), and the memory cell can include the electrical charge.

In some aspects, in a second configuration (e.g., 0 state), the top contact can have a LOW level voltage (e.g., about 0 V or GND), the first gate contact can have a LOW level voltage (e.g., about 0 V or GND), the second gate contact can have a HIGH level voltage (e.g., about 1 V), the third gate contact can have a HIGH level voltage (e.g., about 0.8 V), the bottom contact can have a HIGH level voltage (e.g., about −2 V), and the memory cell can include substantially no electrical charge.

In some aspects, the 3D memory device can perform a block erase operation. In some aspects, different voltage combinations can be applied to the bit line, the word line, the plate line, the third gate contact, and the source line to perform a block erase (e.g., 0 state) operation on a plurality of 3D memory devices in a memory block simultaneously.

In some aspects, the 3D memory device can perform a refresh operation. In some aspects, different voltage combinations can be applied to the bit line, the word line, the plate line, the third gate contact, and the source line to perform a refresh (e.g., “0 state” refresh, “1 state” refresh) operation on the memory cell.

In some aspects, the 3D memory device can perform a block refresh operation. In some aspects, different voltage combinations can be applied to the bit line, the word line, the plate line, the third gate contact, and the source line to perform a block refresh (e.g., “0 state” refresh, “1 state” refresh) operation on a plurality of 3D memory devices in a memory block simultaneously.

In some aspects, the 3D memory device can have a charge retention time of at least 100 ms. In some aspects, the 3D memory device can have a charge retention time of at least 100 ms during high temperature operation (e.g., greater than 85° C.).

In some aspects, the 3D memory device can have a refresh rate of no greater than 10 Hz. In some aspects, the 3D memory device can have a refresh rate of no greater than 10 Hz during high temperature operation (e.g., greater than 85° C.).

In some aspects, the 3D memory device can include a dynamic flash memory (DFM) device. In some aspects, the top contact, the memory cell, and the bottom contact can form a DFM device. In some aspects, the DFM device can increase memory storage efficiency, provide tri-gate control, provide different programming options (e.g., impact ionization, GIDL, GISL), increase read, program, and erase operation rates, decrease leakage current, decrease junction current, decrease power consumption, increase charge retention times, and decrease refresh rates.

In some aspects, the 3D memory device comprises a NAND DFM device. In some aspects, the 3D memory device can include floating-gate transistors (e.g., memory strings) connected in series that resemble a NAND gate.

In some aspects, the top contact can be n-type (e.g., n+), the memory cell can be p-type (e.g., p), and the bottom contact can be n-type (e.g., n+) so that the 3D memory device forms p-type surrounding gate transistors (SGTs) with hole charge carriers. In some aspects, when activated (e.g., source line voltage applied) hole carriers flow through the memory cell from the bottom contact (e.g., source) to the top contact (e.g., drain).

In some aspects, a three-dimensional (3D) memory device can include a memory cell, a top contact coupled to the memory cell, and a bottom contact coupled to the memory cell. In some aspects, the 3D memory device can increase memory storage efficiency, provide tri-gate control, provide different programming options (e.g., impact ionization, GIDL, GISL), increase read, program, and erase operation rates, decrease leakage current, decrease junction current, decrease power consumption, increase charge retention times, and decrease refresh rates.

In some aspects, the memory cell can include a pillar, an insulating layer, a first gate contact, a second gate contact, and a third gate contact. In some aspects, the pillar can be configured to store an electrical charge. In some aspects, the insulating layer can surround the pillar. In some aspects, the first gate contact can surround a first portion of the insulating layer. In some aspects, the first gate contact can be coupled to a TSG line configured to address and non-destructively read the pillar. In some aspects, the second gate contact can surround a second portion of the insulating layer. In some aspects, the second gate contact can be coupled to a plate line configured to program the pillar. In some aspects, the third gate contact can surround a third portion of the insulating layer. In some aspects, the third gate contact can be coupled to a BSG line configured to increase charge retention in the pillar.

In some aspects, the top contact can be coupled to a bit line configured to flow electrical charge through and/or away from the memory cell. In some aspects, the bottom contact can be coupled to a source line configured to flow electrical charge through and/or away from the memory cell. In some aspects, different voltage combinations can be applied to the bit line, the TSG line, the plate line, the BSG line, and the source line to perform read (e.g., non-destructively), program (e.g., 1 state), and erase (e.g., 0 state) operations on the 3D memory device.

In some aspects, the second gate contact can be between the first gate contact and the third gate contact. In some aspects, the third gate contact can be between the second gate contact and the bottom contact. In some aspects, the third gate contact can be configured to increase a distance between the second gate contact and the bottom contact.

In some aspects, in a first configuration (e.g., 1 state), the top contact can have a HIGH level voltage (e.g., about 0.8 V), the first gate contact can have a HIGH level voltage (e.g., about 1.5 V), the second gate contact can have a HIGH level voltage (e.g., about 0.8 V), the third gate contact can have a HIGH level voltage (e.g., about 1 V), the bottom contact can have a LOW level voltage (e.g., about 0 V or GND), and the memory cell can include the electrical charge.

In some aspects, in the first configuration, the third gate contact can be configured to increase a depletion area of the pillar. In some aspects, in the first configuration, the third gate contact applies the HIGH level voltage (e.g., about 1 V) to increase a depletion area of the pillar. In some aspects, in the first configuration, the third gate contact can be configured to decrease a junction leakage in the memory cell. In some aspects, in the first configuration, the third gate contact can be between the second gate contact and the bottom contact to decrease a junction leakage in the memory cell. In some aspects, in the first configuration, the third gate contact can be configured to increase a retention rate of the pillar and decrease a refresh rate of the memory cell. In some aspects, in the first configuration, the third gate contact can apply the HIGH level voltage (e.g., about 1 V) to increase a retention rate of the pillar and decrease a refresh rate of the memory cell.

In some aspects, in a second configuration (e.g., 0 state), the top contact can have a LOW level voltage (e.g., about 0 V or GND), the first gate contact can have a LOW level voltage (e.g., about 0 V or GND), the second gate contact can have a HIGH level voltage (e.g., about 1 V), the third gate contact can have a HIGH level voltage (e.g., about 0.8 V), the bottom contact can have a HIGH level voltage (e.g., about −2 V), and the memory cell can include substantially no electrical charge.

In some aspects, a method for forming a three-dimensional (3D) memory device can include forming an alternating dielectric stack atop a substrate. In some aspects, the method can further include forming a channel trench in the alternating dielectric stack. In some aspects, the method can further include forming a bottom contact in the channel trench. In some aspects, the method can further include forming a pillar atop the bottom contact. In some aspects, the method can further include forming a top contact atop the pillar. In some aspects, the method can further include forming a gate line trench in the alternating dielectric stack. In some aspects, the method can further include removing a portion of the alternating dielectric stack. In some aspects, the method can further include forming a high-k dielectric and conductive gate stack in the removed portion of the alternating dielectric stack to form a memory cell. In some aspects, the memory cell can include a first gate contact, a second gate contact, and a third gate contact. In some aspects, the method can further include forming a gate line slit in the gate line trench. In some aspects, the method can further include forming interconnects to the top contact, the first gate contact, the second gate contact, the third gate contact, and the bottom contact.

In some aspects, the first gate contact can be coupled to a word line configured to address and non-destructively read the pillar. In some aspects, the second gate contact can be coupled to a plate line configured to program the pillar. In some aspects, the third gate contact can be coupled to a dummy line configured to increase a charge flow from the first gate contact to the second gate contact. In some aspects, the third gate contact can be between the first gate contact and the second gate contact.

In some aspects, the first gate contact can be coupled to a word line configured to address and non-destructively read the pillar. In some aspects, the second gate contact can be coupled to a plate line configured to program the pillar. In some aspects, the third gate contact can be coupled to a TSG line configured to create a charge barrier between the first gate contact and the second gate contact to selectively program the pillar. In some aspects, the third gate contact can be between the first gate contact and the second gate contact.

In some aspects, the first gate contact can be coupled to a TSG line configured to address and non-destructively read the pillar. In some aspects, the second gate contact can be coupled to a plate line configured to program the pillar. In some aspects, the third gate contact can be coupled to a BSG line configured to increase charge retention in the pillar. In some aspects, the second gate contact can be between the first gate contact and the third gate contact.

In some aspects, the forming the bottom contact can include epitaxially growing a conductive layer. In some aspects, the forming the bottom contact can include epitaxially growing a doped semiconductor (e.g., silicon). In some aspects, the forming the bottom contact can include a selective epitaxial growth (SEG) process.

In some aspects, the forming the pillar can include epitaxially growing a semiconductor layer. In some aspects, the pillar can be a monolithic vertical pillar. In some aspects, the pillar can be a single semiconductor material (e.g., silicon, doped silicon, monocrystalline silicon, etc.). In some aspects, the pillar can be a monocrystalline material (e.g., silicon, germanium, Group IV semiconductor, Group III-V semiconductor, Group II-VI semiconductor, graphene, sapphire, etc.).

In some aspects, the forming the top contact can include doping the pillar to form a conductive layer. In some aspects, the doping the pillar can include ion implantation. In some aspects, the pillar can include ion implanted dopants to form the top contact. In some aspects, forming the top contact can include epitaxially growing a doped semiconductor (e.g., silicon). In some aspects, forming the top contact can include a SEG process.

In some aspects, the removing the portion of the alternating dielectric stack can include isotropically etching silicon nitride from a lateral edge of the 3D memory device.

In some aspects, the method can include forming a DFM device. In some aspects, forming the top contact, the memory cell, and the bottom contact can form a DFM device. In some aspects, the formed DFM device can increase memory storage efficiency, provide tri-gate control, provide different programming options (e.g., impact ionization, GIDL, GISL), increase read, program, and erase operation rates, decrease leakage current, decrease junction current, decrease power consumption, increase charge retention times, and decrease refresh rates.

In some aspects, the method can include forming a NAND DFM device. In some aspects, forming the NAND DFM device can include forming floating-gate transistors (e.g., memory strings) connected in series that resemble a NAND gate.

Implementations of any of the techniques described above may include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a 3D memory device, according to an exemplary aspect.

FIG. 2 is a schematic perspective illustration of a dual gate SGT device, according to an exemplary aspect.

FIG. 3 is a schematic cross-sectional illustration of a DFM device, according to an exemplary aspect.

FIG. 4 is a schematic cross-sectional illustration of a charge density distribution of the DFM device shown in FIG. 3 for a program state, according to an exemplary aspect.

FIGS. 5A and 5B are schematic cross-sectional illustrations of a tri-gate DFM device, according to an exemplary aspect.

FIG. 6 is a schematic cross-sectional illustration of a charge density distribution of the tri-gate DFM device shown in FIG. 5A for a program state, according to an exemplary aspect.

FIG. 7 is a schematic illustration of voltage distribution in the tri-gate DFM device shown in FIG. 5A for the program state shown in FIG. 6, according to an exemplary aspect.

FIG. 8 is a schematic illustration of voltage distribution in the tri-gate DFM device shown in FIG. 5A for an erase state, according to an exemplary aspect.

FIGS. 9A and 9B are schematic cross-sectional illustrations of a tri-gate DFM device, according to an exemplary aspect.

FIG. 10 is a schematic cross-sectional illustration of a charge density distribution of the tri-gate DFM device shown in FIG. 9A for a program state, according to an exemplary aspect.

FIG. 11 is a schematic illustration of voltage distribution in the tri-gate DFM device shown in FIG. 9A for the program state shown in FIG. 10, according to an exemplary aspect.

FIG. 12 is a schematic illustration of voltage distribution in the tri-gate DFM device shown in FIG. 9A for an erase state, according to an exemplary aspect.

FIGS. 13A through 13J illustrate a manufacturing method for forming the tri-gate

DFM devices shown in FIGS. 5A and 9, according to exemplary aspects.

FIG. 14 illustrates a flow diagram for forming the tri-gate DFM devices shown in FIGS. 5A and 9, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

The term “dynamic random-access memory” or “DRAM” as used herein indicates a volatile memory that uses charge stored on a capacitor to represent information. DRAM stores each bit in a memory cell that includes a transistor and a capacitor (e.g., 1T1C). The 1T1C design can be based on metal-oxide-semiconductor (MOS) technology. Charge levels greater than a certain threshold can represent a first logic level (e.g., 1 state) and charge levels less than another threshold amount can represent a second logic level (e.g., 0 state). Leakage currents and various parasitic effects limit the length of time a capacitor can hold charge. Each time data is read, it must be rewritten to ensure retention and regular data refresh cycles must be performed. DRAM retention times can be as low as 32 ms during high temperature operations (e.g., greater than 85° C.) and can require refresh rates of about 31 Hz.

The term “flash memory” or “flash” as used herein indicates a non-volatile memory that uses charge stored on a floating gate to represent information. Flash stores each bit in a memory cell that includes a transistor with a floating gate. The amount of charge on the floating gate will determine whether the transistor will conduct when a fixed set of read bias conditions are applied. Flash can retain charge for a long period of time (e.g., about 10 years at 85° C.) since the floating gate is completely surrounded by insulators. Further, the act of reading the data can be performed non-destructively without loss of the information. In addition, flash can quickly erase data and entire blocks or pages of data can be erased simultaneously.

The term “NAND” as used herein indicates memory designs or architectures that resemble NAND logic gates (e.g., an inverted AND gate) and connect to memory cells in series (e.g., memory strings). In NAND flash, the relationship between a bit line and a word line resembles a NAND logic gate and can be used for fast writes and high-density arrays. NAND flash can access data sequentially since the transistors in the array are connected in series (e.g., memory strings). NAND flash can be read, programmed (written), and erased in blocks or pages. NAND flash can have a smaller cell size than DRAM but can require additional circuitry to implement.

The term “surrounding gate transistor” or “SGT” as used herein indicates a memory device that has a gate surrounding a channel region of a transistor on all sides.

The term “dynamic flash memory” or “DFM” as used herein indicates a volatile memory that uses a dual gate SGT. The dual gates of the dual gate SGT can include a word line (WL) gate and a plate line (PL) gate. DFM can be capacitor-free and can store charge on a channel region of a transistor. DFM can still requires a refresh cycle but can offer longer retention times, faster operation speeds, and higher density than compared to DRAM or other types of volatile memory. Further, similar to flash, DFM can offer block refresh and block erase operations.

The term “bit line” or “BL” as used herein indicates an array connection to address a particular memory cell in a memory array. A bit line can be connected to a drain of a transistor (e.g., DFM device). A bit line can be connected to two or more serially connected memory cells (e.g., memory strings). Different voltage combinations applied to the bit line can define read, program (write), and erase operations in the memory cell.

The term “source line” or “SL” as used herein indicates an array connection to address a particular memory cell in a memory array. A source line can be connected to a source of a transistor (e.g., DFM device). A source line can be connected to two or more serially connected memory cells (e.g., memory strings). Different voltage combinations applied to the source line can define read, program (write), and erase operations in the memory cell.

The term “word line” or “WL” as used herein indicates an array connection to provide a voltage to a particular memory cell in a memory array to select which row of bits is to be read, programmed, or erased. A word line can act as a top select gate (TSG). A word line can be connected to a portion of a channel or a portion of a body of a transistor (e.g., DFM device). Different voltage combinations applied to the word line can define read, program (write), and erase operations in the memory cell. When the word line is activated, current flows only if charge is already on the memory cell. If there is charge on the channel or body of the memory cell, the read operation recharges the memory cell and is non-destructive. If there is no charge on the channel or body of the memory cell, no current flows and the read is also non-destructive.

The term “plate line” or “PL” as used herein indicates an array connection to provide a voltage to a particular memory cell in a memory array to read, program, or erase charge on the memory cell. A plate line can be connected to a portion of a channel or a portion of a body of a transistor (e.g., DFM device). Different voltage combinations applied to the plate line can define read, program (write), and erase operations in the memory cell. When the plate line is activated, charge flows from the source line (source) to the bit line (drain). When the plate line is deactivated, any remaining charge is stored in the channel or body of the memory cell.

The term “dummy line” or “DMY” as used herein indicates an array connection, separate from a word line, to provide an additional voltage to a particular memory cell in a memory array to increase operating efficiency. A dummy line can be used for impact ionization programming to rapidly increase charge (e.g., holes) conduction generated at a word line contact to flow and increase charge (e.g., holes) in a channel of a memory cell. A dummy line can increase a program (write) rate of a memory cell.

The term “top select gate line” or “TSG” as used herein indicates an array connection to provide a voltage to a particular memory cell in a memory array to select which row of bits is to be read, programmed, or erased. The top select gate line can be used for gate-induced drain leakage (GIDL) programming to create a charge (e.g., hole) barrier to provide selective programming (writing) in a channel of a memory cell. A top select gate line can provide selective programming (writing) and increase a program (write) rate. A top select gate line can provide charge separation between a plate line and a bit line and thereby increase charge retention times and decrease refresh rates in a memory cell. A top select gate line can provide charge separation between a plate line and a bit line and thereby decrease junction leakage. A top select gate line can increase a depletion area of a memory cell.

The term “bottom select gate line” or “BSG” as used herein indicates an array connection to provide a voltage to a particular memory cell in a memory array to select which row of bits is to be read, programmed, or erased. The bottom select gate line can be used for gate-induced source leakage (GISL) programming to create a charge (e.g., hole) barrier to provide selective programming (writing) in a channel of a memory cell. A bottom select gate line can provide selective programming (writing) and increase a program (write) rate. A bottom select gate line can provide charge separation between a plate line and a source line and thereby increase charge retention times and decrease refresh rates in a memory cell. A bottom select gate line can provide charge separation between a plate line and a source line and thereby decrease junction leakage. A bottom select gate line can increase a depletion area of a memory cell.

The term “impact ionization” or “collision ionization” as used herein indicates a programming method to generate electrical charge on a channel through interactions or collisions with charge carriers (e.g., holes). Impact ionization is a carrier generation process by which one energetic charge carrier loses energy through the creation of other charge carriers. For example, an electron with sufficient energy can release a bound electron in the valence band of the semiconductor material to the conduction band thereby creating an electron-hole pair.

The term “gate-induced drain leakage” or “GIDL” as used herein indicates a programming method to generate electrical charge on a channel through drain leakage. GIDL is caused by high electric fields in a drain junction of a memory cell. When a gate is at zero or negative voltage and a bit line has a positive voltage (e.g., above a threshold voltage), various charge generation effects (e.g., avalanche multiplication, band-to-band tunneling) will increase. For example, band-to-band tunneling can occur at the drain-channel junction of the memory cell. Minority carriers (e.g., holes) underneath the gate can flow to the source line to complete the GIDL path.

The term “gate-induced source leakage” or “GISL” as used herein indicates a programming method to generate electrical charge on a channel through source leakage. GISL is caused by high electric fields in a source junction of a memory cell. When a gate is at zero or negative voltage and a source line has a positive voltage (e.g., above a threshold voltage), various charge generation effects (e.g., avalanche multiplication, band-to-band tunneling) will increase. For example, band-to-band tunneling can occur at the source-channel junction of the memory cell. Minority carriers (e.g., holes) underneath the gate can flow to the drain (bit) line to complete the GISL path.

The term “substrate” as used herein indicates a planar wafer on which subsequent layers can be deposited, formed, or grown. A substrate can be formed of a single element (e.g., Si) or a compound material (e.g., GaAs), and may be doped or undoped. For example, a substrate can include silicon (Si), germanium (Ge), silicon-germanium (SiGe), gallium arsenide (GaAs), gallium nitride (GaN), gallium phosphide (GaP), gallium antimonide (GaSb), indium phosphide (InP), indium antimonide (InSb), a Group IV semiconductor, a Group III-V semiconductor, a Group II-VI semiconductor, graphene, sapphire, and/or any other semiconductor material. A substrate can be a monocrystalline material (e.g., monocrystalline Si).

The term “Group III-V semiconductor” as used herein indicates comprising one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}GaAs means the Group III part comprises 25% Al, and thus 75% Ga, while the Group V part comprises 100% As.

The term “Group IV semiconductor” as used herein indicates comprising two or more materials from Group IV of the periodic table (e.g., group 14 elements: carbon (C), silicon (Si), germanium (Ge), tin (Sn), lead (Pb)). Subscripts in chemical symbols of compounds refer to the proportion of that element. For example, Si_{0.25}Ge_{0.75} means the Group IV part comprises 25% Si, and thus 75% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur (S), selenium (Se), tellurium (Te)). The compounds have a 1:1 combination of Group II and Group VI regardless of the number of elements from each group. Subscripts in chemical symbols of compounds refer to the proportion of that element within that group.

The term “doping” or “doped” as used herein indicates that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein indicates a material or layer with a single crystal orientation. In epitaxial growth or deposition, subsequent layers with the same or similar lattice constant follow the registry of the previous crystalline layer and therefore grow with the same crystal orientation or crystallinity.

The term “monocrystalline” as used herein indicates a material or layer having a continuous crystal lattice throughout the material or layer. Monocrystalline can indicate a single crystal or monocrystal (e.g., Si, Ge, GaAs, etc.).

The term “monolithic” as used herein indicates a layer, element, or substrate comprising bulk (e.g., single) material throughout. A monolithic element (e.g., a pillar) can be formed from a single bulk material (e.g., Si).

The term “deposit” or “deposition” as used herein indicates the depositing or growth of a layer on another layer or substrate. Deposition can encompass vacuum deposition, thermal evaporation, arc vaporization, ion beam deposition, e-beam deposition, sputtering, laser ablation, pulsed laser deposition (PLD), physical vapor deposition (PVD), atomic layer deposition (ALD), chemical vapor deposition (CVD), plasma-enhanced CVD (PECVD), low pressure CVD (LPCVD), metal-organic chemical vapor deposition (MOCVD), liquid source misted chemical deposition, spin-coating, epitaxy, vapor-phase epitaxy (VPE), liquid-phase epitaxy (LPE), solid-phase epitaxy (SPE), MBE, atomic layer epitaxy (ALE), molecular-beam epitaxy (MBE), powder bed deposition, and/or other known techniques to deposit material in a layer.

The term “dielectric” as used herein indicates an electrically insulating layer.

Dielectric can encompass oxide, nitride, oxynitride, ceramic, glass, spin-on-glass (SOG), polymer, plastic, thermoplastic, resin, laminate, high-k dielectric, and/or any other electrically insulating material.

The term “high-k dielectric” as used herein indicates a material with a high dielectric constant k or κ (kappa), for example, relative to the dielectric constant of silicon dioxide (SiO₂). High-k dielectrics can be used as a gate dielectric or as another dielectric layer in an electronic device.

The term “high-k metal gate” or “high-k dielectric and conductive gate” or “HKMG” as used herein indicates a process of forming a high-k dielectric layer and a conductive (metal) layer stack in a memory device. HKMG technology can reduce gate leakage, increase transistor capacitance, and provide low power consumption for devices. Two process flows to pattern the HKMG stack are gate-first and gate-last.

The term “epitaxy” or “epitaxial” or “epitaxially” as used herein indicates crystalline growth of material, for example, via high temperature deposition.

The term “selective epitaxial growth” or “SEG” as used herein indicates local growth of an epitaxial layer through a pattern mask on a substrate or a layer. SEG provides epitaxial growth only on the exposed substrate or layer and other regions are masked by a dielectric film or other material that is not reactive to epitaxy.

The term “alternating dielectric stack” as used herein indicates a stack of different alternating dielectric layers in succession. For example, the first dielectric layer can be an oxide (e.g., silicon oxide) and the second dielectric layer can be a nitride (e.g., silicon nitride). The alternating dielectric stack can be arranged in a staircase pattern.

The term “gate line trench” as used herein indicates a trench or hole extending through an alternating dielectric stack of a memory device. The gate line trench can be used to form a gate line slit in the memory device.

The term “gate line slit” or “GLS” as used herein indicates a conductive pathway through an alternating dielectric stack, for example, between adjacent memory blocks or adjacent memory cells. The GLS can provide connection to a HKMG stack in a memory device. The GLS can extend vertically through the alternating dielectric stack and extend horizontally between two adjacent arrays of memory blocks or memory cells.

The term “HIGH level voltage” as used herein indicates an applied voltage not equal to zero (e.g., ±1 V) for a “high” logic state. In some aspects, HIGH level voltage indicates an acceptable input signal voltage range from about 0.8 V to about 5 V for a “high” logic state. In some aspects, HIGH level voltage indicates an acceptable input signal voltage range from about −0.8 V to about −5 V for a “high” logic state.

The term “LOW level voltage” as used herein indicates an applied voltage equal to or greater than zero (e.g., 0 V) for a “low” logic state. In some aspects, LOW level voltage indicates an acceptable input signal voltage range from about 0 V to about 0.8 V for a “low” logic state.

The term “GND” as used herein indicates a ground voltage level (e.g., 0 V).

Aspects of the disclosure may be implemented in hardware, firmware, software, or any combination thereof. Aspects of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; dynamic flash memory (DFM) devices, electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such aspects in more detail, however, it is instructive to present example environments in which aspects of the present disclosure may be implemented.

### Exemplary 3D Memory Device

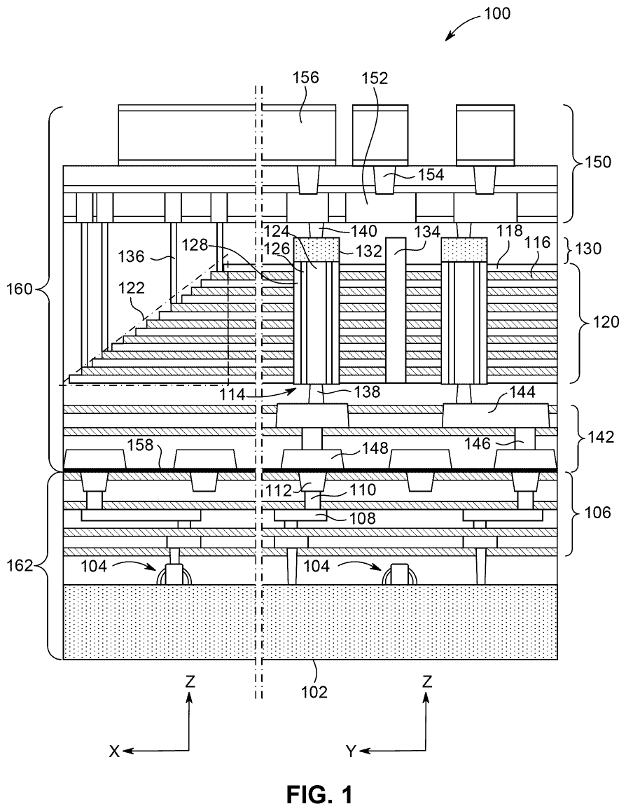

FIG. 1 is a schematic cross-sectional illustration of 3D memory device 100, according to an exemplary aspect. 3D memory device 100 can be configured to increase storage density and incorporate a memory array and peripheral devices for controlling signals to and from the memory array. Although 3D memory device 100 is shown in FIG. 1 as a stand-alone apparatus and/or system, the aspects of this disclosure can be used with other apparatuses, systems, and/or methods, such as, but not limited to, dual gate SGT device 200, DFM device 300, tri-gate DFM device 500, tri-gate DFM device 900, manufacturing method 1300, and/or flow diagram 1400.

As shown in FIG. 1, 3D memory device 100 can include substrate 102, memory array 160, and peripheral device 162. Memory array 160 can include memory stack 120, semiconductor layer 130, array interconnect layer 142, and back-end-of-line (BEOL) interconnect layer 150. Peripheral device 162 can include substrate 102, plurality of transistors 104, and interconnect layer 106. 3D memory device 100 represents an example of a non-monolithic 3D memory device, in which components of the 3D memory device 100 (e.g., peripheral devices and memory arrays) can be formed separately on different substrates and then joined to from 3D memory device 100. This is described in further detail in U.S. Pat. No. 10,867,678, which is incorporated by reference herein in its entirety.

3D memory device 100 can include substrate 102, for example, silicon (e.g., single crystalline silicon), silicon-germanium (SiGe), gallium arsenide (GaAs), germanium (Ge), silicon on insulator (SOI), or any other suitable materials. 3D memory device 100 can include peripheral device 162 on substrate 102. Peripheral device 162 can be formed “on” substrate 102, where the entirety or part of peripheral device 162 is formed in substrate 102 (e.g., below the top surface of substrate 102) and/or directly on substrate 102. Peripheral device 162 can include transistors 104 formed on substrate 102. Isolation regions (e.g., shallow trench isolations (STIs)) and doped regions (e.g., source regions and drain regions of transistors 104) can be formed in substrate 102 as well. In some aspects, peripheral device 162 can be formed on substrate 102 using complementary metal-oxide-semiconductor (CMOS) technology.

3D memory device 100 can include interconnect layer 106 above transistors 104 to transfer electrical signals to and from transistors 104. Interconnect layer 106 can include a plurality of interconnects (also referred to herein as “contacts”), including interconnect lines 108 and vertical interconnect access (via) contacts 110. As used herein, the term “interconnects” can broadly include any suitable types of interconnects, such as front-end-of-line (FEOL) interconnects, middle-end-of-line (MEOL) interconnects, and/or BEOL interconnects.

Interconnect layer 106 can further include one or more interlayer dielectric (ILD) layers (also known as “intermetal dielectric (IMD) layers”) in which interconnect lines 108 and via contacts 110 can form. That is, interconnect layer 106 can include interconnect lines 108 and via contacts 110 in multiple ILD layers. Interconnect lines 108 and via contacts 110 in interconnect layer 106 can include conductive materials including, but not limited to, tungsten (W), cobalt (Co), copper (Cu), aluminum (Al), silicides, or any combination thereof. The ILD layers in interconnect layer 106 can include dielectric materials including, but not limited to, silicon oxide, silicon nitride, silicon oxynitride, low dielectric constant (low-k) dielectrics, or any combination thereof.

In some aspects, interconnect layer 106 can further include bonding contacts 112 at the top surface of interconnect layer 106. Bonding contacts 112 can include conductive materials including, but not limited to, W, Co, Cu, Al, silicides, or any combination thereof. The remaining areas at the top surface of interconnect layer 106 can be formed with dielectric materials including, but not limited to, silicon oxide, silicon nitride, silicon oxynitride, low-k dielectrics, or any combination thereof. Conductive materials (e.g., of bonding contacts 112) and dielectric materials at the top surface of interconnect layer 106 can be used for hybrid bonding as described below in detail.

3D memory device 100 can include memory array 160 above peripheral device 162. It is noted that X, Y, and Z axes are shown in FIG. 1 to further illustrate the spatial relationship of the components in 3D memory device 100. Substrate 102 includes two lateral surfaces (e.g., a top surface and a bottom surface) extending laterally in the X- and Y-directions (i.e., the lateral or width directions). As used herein, whether one component (e.g., a layer or a device) is “on,” “above,” or “below” another component (e.g., a layer or a device) of a semiconductor device (e.g., 3D memory device 100) is determined relative to the substrate of the semiconductor device (e.g., substrate 102) in the Z-direction (i.e., the vertical or thickness direction) when the substrate is positioned in the lowest plane of the semiconductor device in the Z-direction. The same notion for describing spatial relationship is applied throughout the present disclosure.

In some aspects, 3D memory device 100 is a NAND flash memory device in which memory cells are provided in the form of an array of NAND memory strings 114 each extending vertically above peripheral device 162 (e.g., transistors 104) and substrate 102. Memory array 160 can include NAND memory strings 114 that extend vertically through a plurality of alternating conductive/dielectric layer pairs, each including conductor layer 116 and dielectric layer 118. The stacked conductor/dielectric layer pairs are also referred to herein as memory stack 120. Conductor layers 116 and dielectric layers 118 in memory stack 120 alternate in the vertical direction. In other words, except at the top or bottom of memory stack 120, each conductor layer 116 can be adjoined by two dielectric layers 118 on both sides, and each dielectric layer 118 can be adjoined by two conductor layers 116 on both sides. Conductor layers 116 can each have the same thickness or different thicknesses. Similarly, dielectric layers 118 can each have the same thickness or different thicknesses. Conductor layers 116 can include conductive materials including, but not limited to, W, Co, Cu, Al, doped silicon, silicides, or any combination thereof. Dielectric layers 118 can include dielectric materials including, but not limited to, silicon oxide, silicon nitride, silicon oxynitride, or any combination thereof

Memory stack 120 can include an inner region (also known as a “core array region”) and an outer region (also known as a “staircase region”). In some aspects, the inner region is the center region of memory stack 120 where NAND memory strings 114 are formed, and the outer region is the remaining region of memory stack 120 surrounding the inner region (including the sides and edges). As shown in FIG. 1, at least on one lateral side, the outer region of memory stack 120 can include staircase structure 122. The edges of the conductor/dielectric layer pairs in staircase structure 122 of memory stack 120 along the vertical direction away from substrate 102 (the positive Z-direction) are staggered laterally toward NAND memory strings 114. In other words, the edges of memory stack 120 in staircase structure 122 can be tilted toward the inner region as moving away from substrate 102 (from bottom to top). The slope of staircase structure 122 can face away from substrate 102. In some aspects, the length of each conductor/dielectric layer pair of memory stack 120 increases from the top to the bottom.

In some aspects, each two adjacent conductor/dielectric layer pairs in staircase structure 122 are offset by a nominally same distance in the vertical direction (Z-direction) and a nominally same distance in the lateral direction (X-direction). Each offset thus can form a “landing area” for word line fan-out in the vertical direction. Some conductor layers 116 in the conductor/dielectric layer pairs can function as word lines of 3D memory device 100 and extend laterally into staircase structure 122 for interconnection. As shown in FIG. 1, the offset of the edges of each adjacent conductor/dielectric layer pairs in staircase structure 122 is nominally the same, according to some aspects.

As shown in FIG. 1, each NAND memory string 114 can extend vertically through the inner region of memory stack 120 and include semiconductor channel 124 and a dielectric layer (also known as a “memory film”). In some aspects, semiconductor channel 124 includes silicon, such as amorphous silicon, polysilicon, or single crystalline silicon. In some aspects, the memory film is a composite layer including tunneling layer 126, storage layer 128 (also known as a “charge trap/storage layer”), and a blocking layer. Each NAND memory string 114 can have a cylindrical shape (e.g., a pillar shape). Semiconductor channel 124, tunneling layer 126, storage layer 128, and a blocking layer are arranged radially from the center toward the outer surface of the pillar in this order, according to some aspects. Tunneling layer 126 can include silicon oxide, silicon oxynitride, or any combination thereof. Storage layer 128 can include silicon nitride, silicon oxynitride, silicon, or any combination thereof. The blocking layer can include silicon oxide, silicon oxynitride, high dielectric constant (high-k) dielectrics, or any combination thereof.

In some aspects, NAND memory strings 114 further include a plurality of control gates (each being part of a word line). Each conductor layer 116 in memory stack 120 can act as a control gate for each memory cell of NAND memory string 114. Each NAND memory string 114 can include a source select gate at its upper end and a drain select gate at its lower end. As used herein, the “upper end” of a component (e.g., NAND memory string 114) is the end farther away from substrate 102 in the Z-direction, and the “lower end” of the component (e.g., NAND memory string 114) is the end closer to substrate 102 in the Z-direction. For each NAND memory string 114, the drain select gate can be disposed below the source select gate in 3D memory device 100.

In some aspects, 3D memory device 100 further includes semiconductor layer 130 disposed above and in contact with NAND memory strings 114, for example, on the upper end of each NAND memory string 114. Memory stack 120 can be disposed below semiconductor layer 130. Semiconductor layer 130 can be a thinned substrate on which memory stack 120 is formed. In some aspects, semiconductor layer 130 includes semiconductor plugs 132 electrically separated by isolation regions (e.g., STIs). In some aspects, each semiconductor plug 132 is disposed at the upper end of corresponding NAND memory string 114 and functions as the source of corresponding NAND memory string 114 and thus, can be considered as part of corresponding NAND memory string 114. Semiconductor plug 132 can include single crystalline silicon. Semiconductor plug 132 can be undoped, partially doped (in the thickness direction and/or the width direction), or fully doped by p-type or n-type dopants. In some aspects, semiconductor plug 132 can include SiGe, GaAs, Ge, or any other suitable materials.

In some aspects, 3D memory device 100 can further include gate line slit (GLS) 134 that extends vertically in the Z-direction through memory stack 120. GLS 134 can extend along the X-direction which is parallel to staircase structure 122 extending along the X-direction. FIG. 1 shows a cross-sectional view of GLS 134 along the YZ-plane and a separate (orthogonal) cross-sectional view of staircase structure 122 along the XZ-plane. GLS 134 can be used to form the conductor/dielectric layer pairs in memory stack 120 by a gate replacement process. In some aspects, GLS 134 is first filled with dielectric materials, for example, silicon oxide, silicon nitride, or any combination thereof, for separating NAND memory strings 114 into different regions (e.g., memory fingers and/or memory blocks). Then, GLS 134 can be filled with conductive and/or semiconductor materials, for example, W, Co, polysilicon, or any combination thereof, for electrically controlling an array common source (ACS), according to some aspects.

In some aspects, 3D memory device 100 can include local interconnects that are formed in one or more ILD layers and in contact with components in memory stack 120, such as the word lines (e.g., conductor layers 116) and NAND memory strings 114. The interconnects are referred to herein as “local interconnects” as they are in contact with the components in memory stack 120 directly for fan-out. The local interconnects can include word line contacts 136, bit line contacts 138, and source line contacts 140. Each local interconnect can include an opening (e.g., a via hole or a trench) filled with conductive materials including, but not limited to, W, Co, Cu, Al, silicides, or any combination thereof.

Word line contacts 136 can extend vertically through one or more ILD layers. Each word line contact 136 can have its lower end in contact with corresponding conductor layer 116 (e.g., at the landing area) in staircase structure 122 of memory stack 120 to individually address a corresponding word line of 3D memory device 100. In some aspects, each word line contact 136 is disposed above corresponding conductor layer 116. Each bit line contact 138 can be disposed below memory stack 120 and have its upper end in contact with the lower end (e.g., the drain end) of corresponding NAND memory string 114 to individually address corresponding NAND memory string 114. Multiple bit line contacts 138 are disposed below and in contact with multiple NAND memory strings 114, respectively, according to some aspects. As shown in FIG. 1, word line contacts 136 and bit line contacts 138 fan-out the corresponding memory stack components toward opposite vertical directions (the positive and negative Z-directions). Source line contacts 140 can extend vertically through one or more ILD layers. Each source line contact 140 can have its lower end in contact with corresponding semiconductor plug 132 (e.g., the source) of NAND memory string 114. In some aspects, each source line contact 140 is disposed above corresponding NAND memory string 114.

Similar to peripheral device 162, memory array 160 of 3D memory device 100 can also include interconnect layers for transferring electrical signals to and from NAND memory strings 114. As shown in FIG. 1, 3D memory device 100 can include array interconnect layer 142 below NAND memory strings 114. Array interconnect layer 142 can include a plurality of interconnects, including array interconnect lines 144 and array via contacts 146 in one or more ILD layers. In some aspects, array interconnect layer 142 includes array bonding contacts 148 at its bottom surface. Array interconnect lines 144, array via contacts 146, and array bonding contacts 148 can include conductive materials including, but not limited to, W, Co, Cu, Al, silicides, or any combination thereof. The remaining areas at the bottom surface of array interconnect layer 142 can be formed with dielectric materials including, but not limited to, silicon oxide, silicon nitride, silicon oxynitride, low-k dielectrics, or any combination thereof. Conductive materials (of array bonding contacts 148) and dielectric materials at the bottom surface of array interconnect layer 142 can be used for hybrid bonding as described below in detail.

As shown in FIG. 1, BEOL interconnect layer 150 can be disposed above NAND memory strings 114 and semiconductor layer 130 and can include interconnects, such as BEOL interconnect lines 152 and BEOL via contacts 154 in one or more ILD layers. BEOL interconnect layer 150 can further include BEOL contact pads 156 and a redistribution layer at the top surface of 3D memory device 100 for wire bonding and/or bonding with an interposer. BEOL interconnect layer 150 and array interconnect layer 142 can be formed at opposite sides of NAND memory strings 114. In some aspects, BEOL interconnect lines 152, BEOL via contacts 154, and BEOL contact pads 156 in BEOL interconnect layer 150 can transfer electrical signals between 3D memory device 100 and external circuits. BEOL interconnect layer 150 can be electrically connected to memory stack 120 by the local interconnects. As shown in FIG. 1, each word line contact 136 can have its upper end in contact with BEOL interconnect layer 150. Similarly, each source line contact 140 can have its upper end in contact with BEOL interconnect layer 150. The arrangement and configuration of staircase structure 122 and semiconductor layer 130 allow direct fan-out of the word lines (e.g., conductor layers 116) and the sources of NAND memory strings 114 through the local interconnects (e.g., word line contacts 136 and source line contacts 140) and BEOL interconnect layer 150 without detouring through array interconnect layer 142.

In some aspects, 3D memory device 100 further includes one or more through array contacts (TACs) that extend vertically through memory stack 120. Each TAC can extend through the entirety of memory stack 120, (e.g., all the conductor/dielectric layer pairs therein) and have its upper end in contact with BEOL interconnect layer 150 and its lower end in contact with array interconnect layer 142. TACs can thus make electrical connections between interconnect layer 106 and BEOL interconnect layer 150 and carry electrical signals from peripheral device 162 to BEOL interconnect layer 150 of 3D memory device 100.

Bonding interface 158 can be formed between interconnect layer 106 and array interconnect layer 142. Bonding contacts 112 and be bonded with array bonding contacts 148 at bonding interface 158. As shown in FIG. 1, peripheral device 162 (e.g., transistors 104) can be disposed below memory array 160 (e.g., NAND memory strings 114) in 3D memory device 100 after bonding. In 3D memory device 100, bonding interface 158 is disposed between memory array 160 (e.g., NAND memory strings 114) and peripheral device 162 (e.g., transistors 104), according to some aspects. Interconnect layer 106 can be between bonding interface 158 and peripheral device 162 (e.g., transistors 104), and array interconnect layer 142 can be between bonding interface 158 and memory array 160 (e.g., NAND memory strings 114).

In some aspects, a first semiconductor structure (e.g., memory array 160), including

NAND memory strings 114, semiconductor layer 130 (e.g., a thinned substrate), array interconnect layer 142, BEOL interconnect layer 150, and word line contacts 136, can be bonded to a second semiconductor structure (e.g., peripheral device 162), including substrate 102, transistors 104, and interconnect layer 106, in a face-to-face manner at bonding interface 158. Array interconnect layer 142 can contact interconnect layer 106 at bonding interface 158. Peripheral device 162 and memory array 160 can be bonded using hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric- dielectric bonding simultaneously. The metal-metal bonding can be formed between array bonding contacts 148 and bonding contacts 112, and the dielectric-dielectric bonding can be formed between the dielectric materials at the remaining areas at bonding interface 158.

### Exemplary Dual Gate Surrounding Gate Transistor (SGT) Device

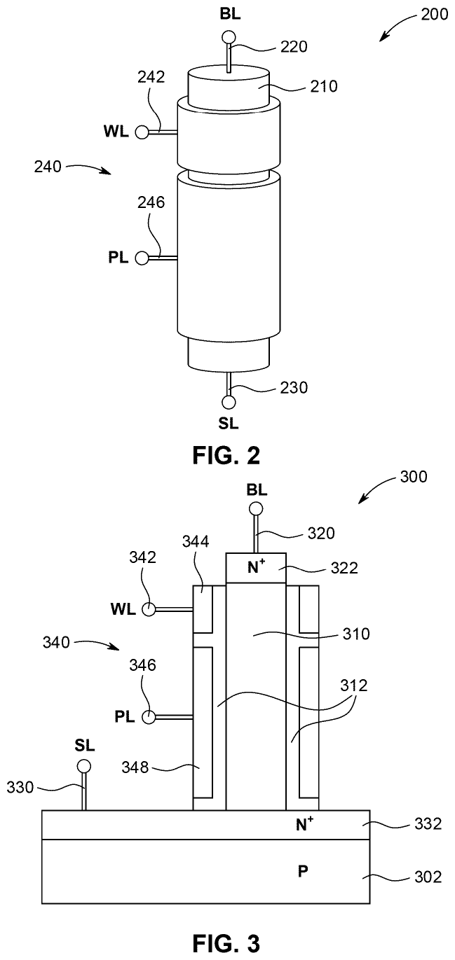

FIG. 2 is a schematic perspective illustration of dual gate SGT device 200, according to an exemplary aspect. Dual gate SGT device 200 can be configured to provide two gates (e.g., word line 242 and plate line 246) surrounding a channel region (e.g., pillar 210) on all sides. Dual gate SGT device 200 can be further configured to operate as a volatile capacitor-free 3D memory device. Although dual gate SGT device 200 is shown in FIG. 2 as a stand-alone apparatus and/or system, the aspects of this disclosure can be used with other apparatuses, systems, and/or methods, such as, but not limited to, 3D memory device 100, DFM device 300, tri-gate DFM device 500, tri-gate DFM device 900, manufacturing method 1300, and/or flow diagram 1400.

As shown in FIG. 2, dual gate SGT device 200 can include pillar 210, bit line (BL) 220, source line (SL) 230, and SGT cell 240. Pillar 210 can be configured to store charge (e.g., holes). BL 220 can be configured to address pillar 210 in dual gate SGT device 200 and act as a drain connection to pillar 210. SL 230 can be configured to address pillar 210 in dual gate SGT device 200 and act as a source connection to pillar 210. SGT cell 240 can be configured to address pillar 210 in dual gate SGT device 200 and act as a gate connection to pillar 210. In some aspects, different voltage combinations applied to BL 220, SL 230, and SGT cell 240 can define read, program (write), and erase operations in dual gate SGT device 200.

SGT cell 240 can include word line (WL) 242 and plate line (PL) 246. WL 242 can be configured to address pillar 210 in dual gate SGT device 200 and act as a first gate connection to pillar 210. In some aspects, WL 242 can act as a top select gate connection. In some aspects, WL 242 can provide a voltage to read, program, or erase charge on pillar 210. PL 246 can be configured to address pillar 210 in dual gate SGT device 200 and act as a second gate connection of pillar 210. In some aspects, PL 246 can act as a traditional current-valve gate (e.g., similar to a metal-oxide-semiconductor field-effect transistor (MOSFET) gate) for pillar 210 and cover a majority of a length of pillar 210. In some aspects, PL 246 can provide a voltage to read, program, or erase charge on pillar 210. In some aspects, dual gate SGT device 200 can form part of DFM device 300 shown in FIG. 3.

### Exemplary Dynamic Flash Memory (DFM) Device

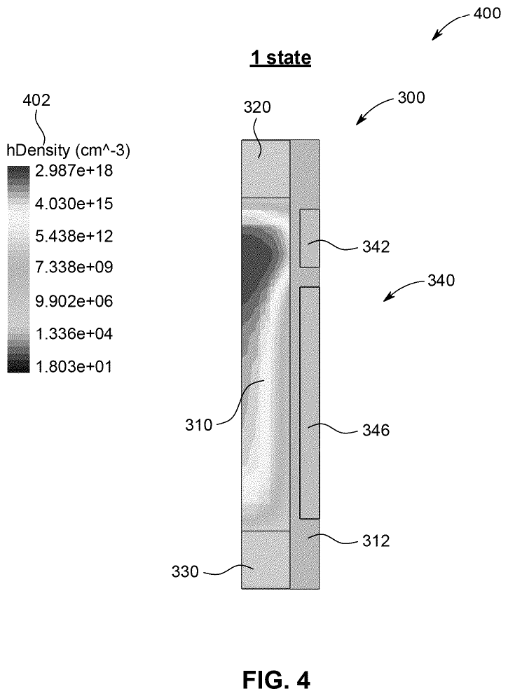

FIGS. 3 and 4 illustrate DFM device 300, according to exemplary aspects. FIG. 3 is a schematic cross-sectional illustration of DFM device 300, according to an exemplary aspect. FIG. 4 is a schematic cross-sectional illustration of charge density distribution 400 of DFM device 300 shown in FIG. 3 for a program state (1 state), according to an exemplary aspect. DFM device 300 can be configured to include dual gate SGT device 200 in a vertical arrangement on substrate 302 and operate as a volatile capacitor-free 3D memory device. DFM device 300 can be further configured to provide faster operation speeds and higher density than DRAM or other types of volatile memory. DFM device 300 can be further configured to provide block refresh and block erase operations similar to flash memory functionality. Although DFM device 300 is shown in FIGS. 3 and 4 as a stand-alone apparatus and/or system, the aspects of this disclosure can be used with other apparatuses, systems, and/or methods, such as, but not limited to, 3D memory device 100, dual gate SGT device 200, tri-gate DFM device 500, tri-gate DFM device 900, manufacturing method 1300, and/or flow diagram 1400.

As shown in FIG. 3, DFM device 300 can include substrate 302, pillar 310, dielectric 312, bit line (BL) 320, BL contact 322, source line (SL) 330, SL contact 332, and DFM cell 340. Substrate 302 can be configured to support pillar 310, dielectric 312, BL contact 322, SL contact 332, and DFM cell 340. Substrate 302 can be coupled to SL contact 332. In some aspects, substrate 302 can be a p-type semiconductor (e.g., p), for example, doped silicon. Pillar 310 can be configured to store charge (e.g., holes). Pillar 310 can be between BL contact 322 and SL contact 332. Dielectric 312 can surround pillar 310 and be configured to provide electrical insulation between pillar 310 and DFM cell 340 (e.g., word line contact 344 and plate line contact 346). In some aspects, dielectric 312 can be a high-k dielectric configured to increase a gate capacitance and decrease a leakage current in pillar 310.

BL 320 can be configured to address pillar 310 in DFM device 300 and be coupled to BL contact 322. BL contact 322 can be configured to act as a drain connection to pillar 310. In some aspects, BL contact 322 can be n-type (e.g., n+) and pillar 310 can be p-type (e.g., p). SL 330 can be configured to address pillar 310 in DFM device 300 and be coupled to SL contact 332. SL contact 332 can be configured to act as a source connection to pillar 310. In some aspects, SL contact 332 can be n-type (e.g., n+) and pillar 310 can be p-type (e.g., p). DFM cell 340 can be configured to address pillar 310 in DFM device 300 and act as a gate connection to pillar 310. In some aspects, different voltage combinations applied to BL 320, SL 330, and DFM cell 340 can define read, program (write), and erase operations in DFM device 300.

DFM cell 340 can include word line (WL) 342, WL contact 344, plate line (PL) 346, and PL contact 348. WL 342 can be configured to address pillar 310 in DFM device 300 and be coupled to WL contact 344. WL contact 344 can be configured to act as a first gate connection to pillar 310. WL contact 344 can surround dielectric 312 which surrounds pillar 310 thereby forming a first concentric transistor. In some aspects, WL contact 344 can include a conductive material (e.g., metal, polysilicon, tungsten, etc.). In some aspects, WL 342 can act as a top select gate connection. In some aspects, WL 342 can provide voltage to WL contact 344, thereby inducing an electric field within pillar 310, to read, program, or erase charge on pillar 310.

PL 346 can be configured to address pillar 310 in DFM device 300 and be coupled to PL contact 348. PL contact 348 can be configured to act as a second gate connection to pillar 310. PL contact 348 can surround dielectric 312 which surrounds pillar 310 thereby forming a second concentric transistor. In some aspects, PL contact 348 can include a conductive material (e.g., metal, polysilicon, tungsten, etc.). In some aspects, PL 346 can act as a traditional current-valve gate (e.g., similar to a MOSFET gate) for pillar 310 and cover a majority of a length of pillar 310. In some aspects, PL 346 can provide voltage to PL contact 348, thereby inducing an electric field within pillar 310, to read, program, or erase charge on pillar 310.

As shown in FIG. 4, charge density distribution 400 shows charge (e.g., hole) density 402 within DFM device 300 for a program state (1 state) after 100 ms at an operating temperature of 85° C. Charge density distribution 400 can include charge (e.g., hole) density 402, which can range from about 1.8×10¹ cm⁻³ to about 3×10¹⁸ cm⁻³. The program state (1 state) represents a program (write) operation on DFM device 300, whereby different voltage combinations applied to BL 320, SL 330, WL 342, and PL 346 form charge (e.g., holes) on pillar 310 of DFM device 300. In some aspects, as shown in FIG. 4, in the 1 state, only a small portion of pillar 310 retains charge of at least 1×10¹⁷ cm⁻³ after 100 ms at an operating temperature of 85° C. For example, a portion of pillar 310 adjacent PL contact 346 retains charge no greater than 1×10¹⁷ cm⁻³.

### Exemplary Tri-Gate DFM Devices

As discussed above, DRAM is a volatile memory that uses charge stored on a capacitor to represent information. DRAM stores each bit in a memory cell that includes a transistor and a capacitor (e.g., 1T1C). Charge levels greater than a certain threshold can represent a first logic level (e.g., 1 state) and charge levels less than another threshold amount can represent a second logic level (e.g., 0 state). Leakage currents and various parasitic effects limit the length of time a capacitor can hold charge. Each time data is read, it must be rewritten to ensure retention and regular data refresh cycles must be performed. DRAM retention times can be as low as 32 ms during high temperature operations (e.g., greater than 85° C.) and can require refresh rates of about 31 Hz.

Flash is a non-volatile memory that uses charge stored on a floating gate to represent information. Flash stores each bit in a memory cell that includes a transistor with a floating gate. The amount of charge on the floating gate will determine whether the transistor will conduct when a fixed set of read bias conditions are applied. Flash can retain charge for a long period of time since the floating gate is completely surrounded by insulators. Further, the act of reading the data can be performed non-destructively without loss of the information. In addition, flash can quickly erase entire blocks or pages of data simultaneously (e.g., NAND flash).

Current 1T1C DRAM is approaching a process limit. The manufacturing of 1T1C DRAM devices with small-node capacitors to retain charge is becoming more difficult due to increased current leakage, increased power consumption, degraded operating voltage margins, and decreased retention times. Further, current single transistor (1T) capacitor-free DRAM (e.g., ZRAM, TTRAM, ARAM, etc.) devices need further improvement and optimization for manufacturable integration and operation solutions. Current 1T DRAM devices have serious problems due to junction leakage and large capacitive coupling between word lines and the transistor floating body. In addition, current 1T DRAM devices have extremely narrow operational voltage margins between first and second logic levels (e.g., 1 state and 0 state).

Aspects of tri-gate DFM apparatuses, systems, and methods as discussed below can provide a capacitor-free dynamic random-access memory device to increase memory storage storage efficiency, provide tri-gate control, provide different programming options (e.g., impact ionization, GIDL, GISL), increase read, program, and erase operation rates, decrease leakage current, decrease junction current, decrease power consumption, increase charge retention times, and/or decrease refresh rates.

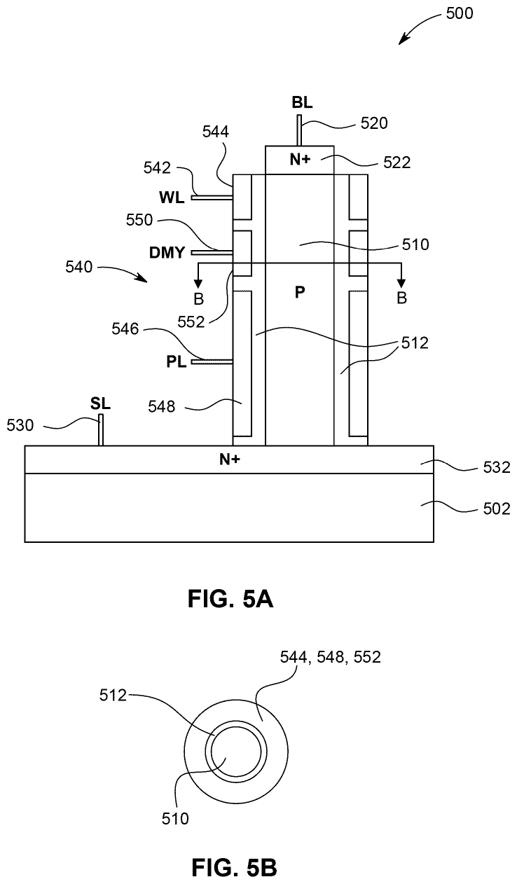

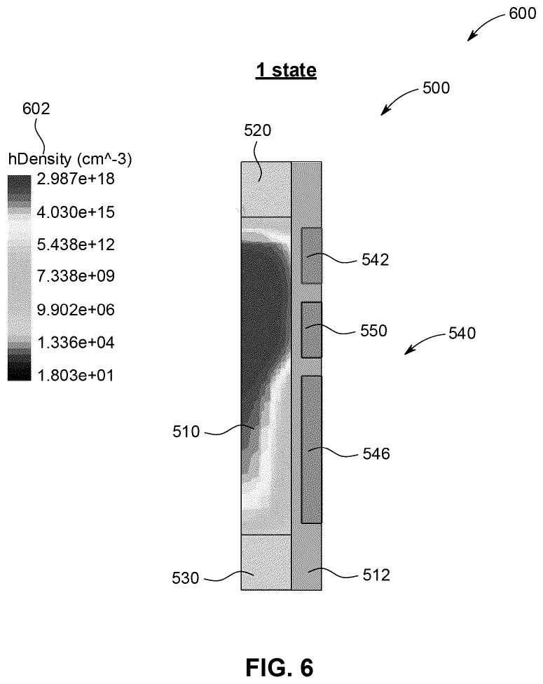

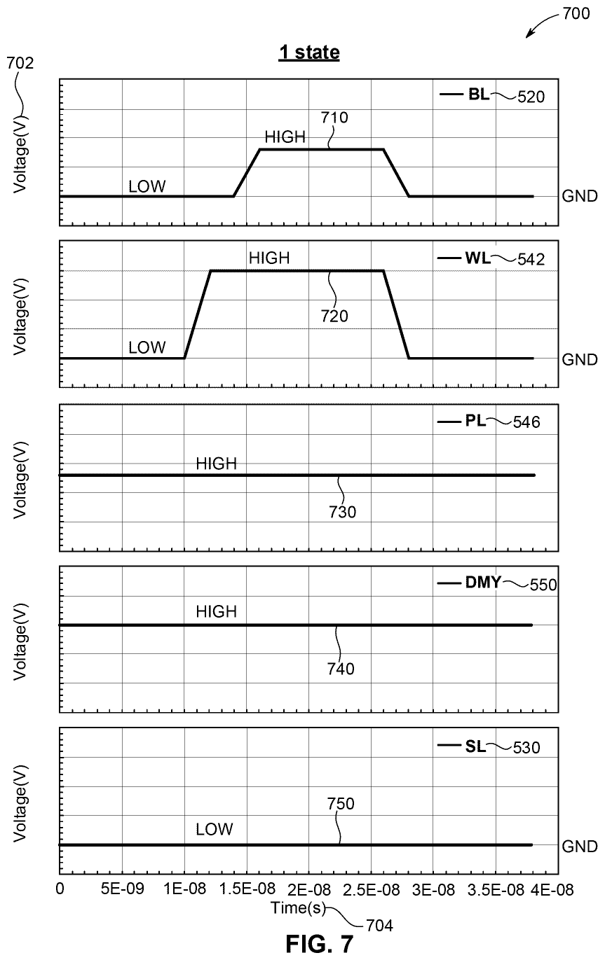

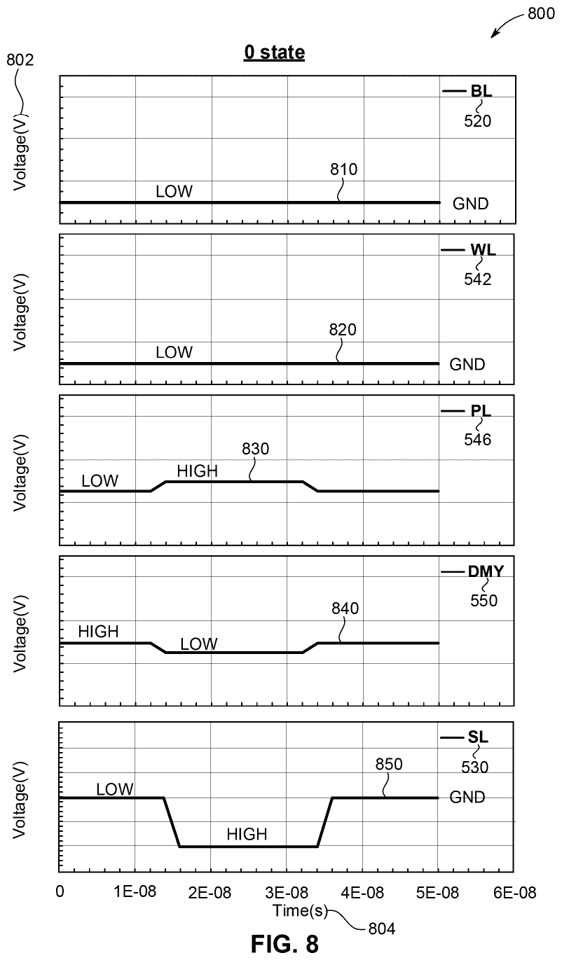

FIGS. 5A-8 illustrate tri-gate DFM device 500, according to exemplary aspects. FIGS. 5A and 5B are schematic cross-sectional illustrations of tri-gate DFM device 500, according to an exemplary aspect. FIG. 6 is a schematic cross-sectional illustration of charge density distribution 600 of tri-gate DFM device 500 shown in FIG. 5A for a program state (1 state), according to an exemplary aspect. FIG. 7 is a schematic illustration of voltage distribution 700 in tri-gate DFM device 500 shown in FIG. 5A for the program state (1 state) shown in FIG. 6, according to an exemplary aspect. FIG. 8 is a schematic illustration of voltage distribution 800 in tri-gate DFM device 500 shown in FIG. 5A for an erase state (0 state), according to an exemplary aspect.

Tri-gate DFM device 500 can be configured to operate as a volatile capacitor-free dynamic random-access 3D memory device. Tri-gate DFM device 500 can be further configured to increase memory storage efficiency. Tri-gate DFM device 500 can be further configured to provide tri-gate control and different programming options (e.g., impact ionization, GIDL, GISL). Tri-gate DFM device 500 can be further configured to increase read, program, and erase operation rates. Tri-gate DFM device 500 can be further configured to decrease leakage current, decrease junction current, and decrease power consumption. Tri-gate DFM device 500 can be further configured to increase charge retention times (e.g., greater than 100 ms at 85° C. operating temperature) and decrease refresh rates (e.g., less than 10 Hz).

Tri-gate DFM device 500 can be further configured to provide faster operation speeds and higher density than DRAM or other types of volatile memory. Tri-gate DFM device 500 can be further configured to provide block refresh and block erase operations similar to flash memory functionality. Although tri-gate DFM device 500 is shown in FIGS. 5A-8 as a stand-alone apparatus and/or system, the aspects of this disclosure can be used with other apparatuses, systems, and/or methods, such as, but not limited to, 3D memory device 100, dual gate SGT device 200, DFM device 300, manufacturing method 1300, and/or flow diagram 1400.

As shown in FIG. 5A, tri-gate DFM device 500 can include substrate 502, pillar 510, dielectric 512, bit line (BL) 520, BL contact 522, source line (SL) 530, SL contact 532, and DFM cell 540. In some aspects, tri-gate DFM device 500 can be a vertical 3D memory device. In some aspects, tri-gate DFM device 500 can include one or more DFM devices (e.g., DFM device 300 shown in FIG. 3). In some aspects, tri-gate DFM device 500 can include one or more NAND DFM devices. In some aspects, tri-gate DFM device 500 can be part of a memory array, for example, memory array 160 of 3D memory device 100 shown in FIG. 1.

Substrate 502 can be configured to support pillar 510, dielectric 512, BL contact 522, SL contact 532, and DFM cell 540. Substrate 502 can be coupled to SL contact 532. In some aspects, substrate 502 can be a p-type semiconductor (e.g., p), for example, doped silicon. In some aspects, substrate 502 can include any planar wafer material, for example, Si, Ge, SiGe, GaAs, Group IV semiconductor, Group III-V semiconductor, Group II-VI semiconductor, graphene, sapphire, and/or any other semiconductor.

Pillar 510 can be configured to store electrical charge (e.g., holes). Pillar 510 can be between BL contact 522 and SL contact 532. In some aspects, pillar 510 can include a semiconductor material, for example, Si, doped Si, Ge, SiGe, GaAs, Group IV semiconductor, Group III-V semiconductor, Group II-VI semiconductor, graphene, sapphire, and/or any other semiconductor. In some aspects, pillar 510 can be doped (e.g., p-type). In some aspects, pillar 510 can have a doping concentration of about 1×10¹⁶ cm⁻³ to about 5×10¹⁸ cm⁻³. For example, pillar 510 can have a doping concentration of about 1×10¹⁸ cm⁻³. In some aspects, pillar 510 can have a diameter of about 1 nm to about 100 nm. For example, pillar 510 can have a diameter of about 50 nm. In some aspects, pillar 510 can be monolithic. For example, as shown in FIG. 5A, pillar 510 can be a single monolithic vertical pillar. In some aspects, pillar 510 can be formed from the same material as substrate 502.

Dielectric 512 can be configured to provide electrical insulation between pillar 510 and DFM cell 540. Dielectric 512 can surround pillar 510. In some aspects, dielectric 512 can include a dielectric material, for example, oxide, nitride, oxynitride, ceramic, glass, SOG, polymer, plastic, thermoplastic, resin, laminate, high-k dielectric, a combination thereof, and/or any other electrically insulating material. In some aspects, dielectric 312 can be a high-k dielectric configured to increase a gate capacitance and decrease a leakage current in pillar 510. In some aspects, dielectric 512 can have a radial thickness of about 1 nm to about 30 nm. For example, dielectric 512 can have a radial thickness of about 3 nm. In some aspects, dielectric 512 can be monolithic. For example, as shown in FIG. 5A, dielectric 512 can be a single monolithic vertical dielectric.

BL 520 can be configured to address pillar 510 in tri-gate DFM device 500. BL 520 can be further configured to flow electrical charge through DFM cell 540. BL 520 can be coupled to BL contact 522. BL contact 522 can be configured to act as a drain connection to pillar 510. BL contact 522 can be coupled to a top side of DFM cell 540. In some aspects, BL contact 522 can be n-type (e.g., n+) and pillar 510 can be p-type (e.g., p). In some aspects, BL contact 522 can include a conductive material, for example, a metal, a doped semiconductor, polysilicon, tungsten, and/or any other suitable conductor.

SL 530 can be configured to address pillar 510 in tri-gate DFM device 500. SL 530 can be further configured to flow electrical charge through DFM cell 540. SL 530 can be coupled to SL contact 532. SL contact 532 can be configured to act as a source connection to pillar 510. SL contact 532 can be coupled to a bottom side of DFM cell 540. In some aspects, SL contact 532 can be n-type (e.g., n+) and pillar 510 can be p-type (e.g., p). In some aspects, SL contact 532 can include a conductive material, for example, a metal, a doped semiconductor, polysilicon, tungsten, and/or any other suitable conductor. In some aspects, different voltage combinations applied to BL 520, SL 530, and DFM cell 540 can define read, program (write), and erase operations in tri-gate DFM device 500.

DFM cell 540 can be configured to read, program, and erase electrical charge on pillar 510. DFM cell 540 can be coupled to BL contact 522 and SL contact 532. DFM cell 540 can include word line (WL) 542, WL contact 544, plate line (PL) 546, PL contact 548, dummy line (DMY) 550, and DMY contact 552. In some aspects, DFM cell 540 can be configured for impact ionization programming, GIDL programming, or both.

WL 542 can be configured to address pillar 510 in tri-gate DFM device 500. WL 542 can be further configured to address and non-destructively read electrical charge on pillar 510. In some aspects, WL 542 can act as a top select gate connection. WL 542 can be coupled to WL contact 544. WL contact 544 can be configured to act as a first gate connection to pillar 510. WL contact 544 can surround a first portion of dielectric 512 which surrounds a first portion of pillar 510 thereby forming a first concentric transistor in DFM cell 540. In some aspects, WL contact 544 can include a conductive material (e.g., metal, polysilicon, tungsten, etc.). In some aspects, WL 542 can provide voltage to WL contact 544, thereby inducing an electric field within pillar 510, to read, program, or erase charge on pillar 510. In some aspects, as shown in FIG. 5A, WL contact 544 can be between BL contact 522 and PL contact 548.

PL 546 can be configured to address pillar 510 in tri-gate DFM device 500. PL 546 can be further configured to program (e.g., write) pillar 510. In some aspects, PL 546 can act as a traditional current-valve gate (e.g., similar to a MOSFET gate) for pillar 510 and cover a majority of a length of pillar 510. PL 546 can be coupled to PL contact 548. PL contact 548 can be configured to act as a second gate connection to pillar 510. PL contact 548 can surround a second portion of dielectric 512 which surrounds a second portion of pillar 510 thereby forming a second concentric transistor in DFM cell 540. In some aspects, PL contact 548 can include a conductive material (e.g., metal, polysilicon, tungsten, etc.). In some aspects, PL 546 can provide voltage to PL contact 548, thereby inducing an electric field within pillar 510, to read, program, or erase charge on pillar 510. In some aspects, DFM cell 540 can form a DFM device, for example, DFM device 300 shown in FIG. 3.

DMY 550 can be configured to address pillar 510 in tri-gate DFM device 500. DMY 550 can be further configured to program (e.g., write) pillar 510. In some aspects, DMY 550 can control electrical charge conduction in pillar 510. For example, DMY 550 can control electrical charge conduction between WL contact 544 and PL contact 546. DMY 550 can be coupled to DMY contact 552. DMY contact 552 can be configured to act as a third gate connection to pillar 510. DMY contact 552 can surround a third portion of dielectric 512 which surrounds a third portion of pillar 510 thereby forming a third concentric transistor in DFM cell 540. In some aspects, DMY contact 552 can include a conductive material (e.g., metal, polysilicon, tungsten, etc.). In some aspects, as shown in FIG. 5A, DMY contact 552 can be between WL contact 544 and PL contact 548. In some aspects, DMY 550 can provide voltage to DMY contact 552, thereby inducing an electric field within pillar 510, to read, program, or erase charge on pillar 510. In some aspects, different voltage combinations applied to BL 520, SL 530, WL 542, PL 546, and DMY 550 can define read, program (write), and erase operations in tri-gate DFM device 500.

In some aspects, DMY 550 can be configured to increase a program (write) rate of pillar 510. For example, for impact ionization programming, DMY 550 can increase a charge flow from WL contact 544 to PL contact 548 thereby increasing the program (write) rate (e.g., a write rate greater than 100 MHz with less than 10 ns write time). In some aspects, DMY 550 can increase a charge flow in pillar 510. For example, the charge flow can have a charge density greater than about 1×10¹⁷ cm⁻³.

In some aspects, DMY 550 can decrease a program (write) time in tri-gate DFM device 500 to about 20 ns to about 1 ns. For example, the program (write) time can be about 5 ns. In some aspects, DMY 550 can increase a program (write) rate in tri-gate DFM device 500 to about 50 MHz to about 1 GHz. For example, the program (write) rate can be about 200 MHz.

In some aspects, DMY 550 can decrease a read time in tri-gate DFM device 500 to about 10 ns to about 100 ps. For example, the read time can be about 1 ns. In some aspects, DMY 550 can increase a read rate in tri-gate DFM device 500 to about 100 MHz to about 10 GHz. For example, the read rate can be about 1 GHz.

In some aspects, DMY 550 can decrease an erase time in tri-gate DFM device 500 to about 20 ns to about 1 ns. For example, the erase time can be about 5 ns. In some aspects, DMY 550 can increase an erase rate in tri-gate DFM device 500 to about 50 MHz to about 1 GHz. For example, the erase rate can be about 200 MHz.

As shown in FIG. 6, charge density distribution 600 shows charge (e.g., hole) density 602 within tri-gate DFM device 500 for a first logic state (1 state) after 100 ms at an operating temperature of 85° C. In some aspects, as shown in FIG. 6, in the first logic state (1 state), pillar 510 of DFM cell 540 can include electrical charge (e.g., holes). Charge density distribution 600 can include charge (e.g., hole) density 602, which can range from about 1.8×10¹ cm⁻³ to about 3×10¹⁸ cm⁻³. The first logic state (1 state) represents a program (write) operation on tri-gate DFM device 500, whereby different voltage combinations applied to BL 520, SL 530, WL 542, PL 546, and DMY 550 form charge (e.g., holes) on pillar 510 of tri-gate DFM device 500. In some aspects, as shown in FIG. 6, in the first logic state (1 state), a majority of pillar 510 retains charge of at least 1×10¹⁷ cm⁻³ after 100 ms at an operating temperature of 85° C. For example, a portion of pillar 510 adjacent PL contact 548 retains charge of at least 1×10¹⁷ cm⁻³.

As shown in FIG. 7, voltage distribution 700 shows BL voltage waveform 710, WL voltage waveform 720, PL voltage waveform 730, DMY voltage waveform 740, and SL voltage waveform 750 within tri-gate DFM device 500 for the first logic state (1 state) after 100 ms at an operating temperature of 85° C. Voltage distribution 700 shows voltage 702 applied by BL 520, SL 530, WL 542, PL 546, and DMY 550 to pillar 510 in tri-gate DFM device 500 over time 704. In some aspects, as shown in FIG. 7, in the first logic state (1 state), BL contact 522 can apply a HIGH level voltage (e.g., about 0.8 V), WL contact 544 can apply a HIGH level voltage (e.g., about 1.5 V), PL contact 548 can apply a HIGH level voltage (e.g., about 0.8 V), DMY contact 552 can apply a HIGH level voltage (e.g., about 1 V), and SL contact 532 can apply a LOW level voltage (e.g., about 0 V or GND). In some aspects, as shown in FIGS. 6 and 7, voltage distribution 700 applied to BL 520, SL 530, and DFM cell 540 can define first logic state (1 state) in tri-gate DFM device 500, for example, by storing charge (e.g. holes) on pillar 510.

As shown in FIG. 8, voltage distribution 800 shows BL voltage waveform 810, WL voltage waveform 820, PL voltage waveform 830, DMY voltage waveform 840, and SL voltage waveform 850 within tri-gate DFM device 500 for a second logic state (0 state) after 100 ms at an operating temperature of 85° C. Voltage distribution 800 shows voltage 802 applied by BL 520, SL 530, WL 542, PL 546, and DMY 550 to pillar 510 in tri-gate DFM device 500 over time 804. In some aspects, as shown in FIG. 8, in the second logic state (0 state), BL contact 522 can apply a LOW level voltage (e.g., about 0 V or GND), WL contact 544 can apply a LOW level voltage (e.g., about 0 V or GND), PL contact 548 can apply a HIGH level voltage (e.g., about 1 V), DMY contact 552 can apply a HIGH level voltage (e.g., about 0.8 V), and SL contact 532 can apply a HIGH level voltage (e.g., about −2 V). In some aspects, in the second logic state (0 state), SL contact 532 can apply a HIGH level voltage (e.g., about −1 V to about −5 V). In some aspects, as shown in FIG. 8, voltage distribution 800 applied to BL 520, SL 530, and DFM cell 540 can define second logic state (0 state) in tri-gate DFM device 500, for example, by removing charge (e.g. holes) on pillar 510.

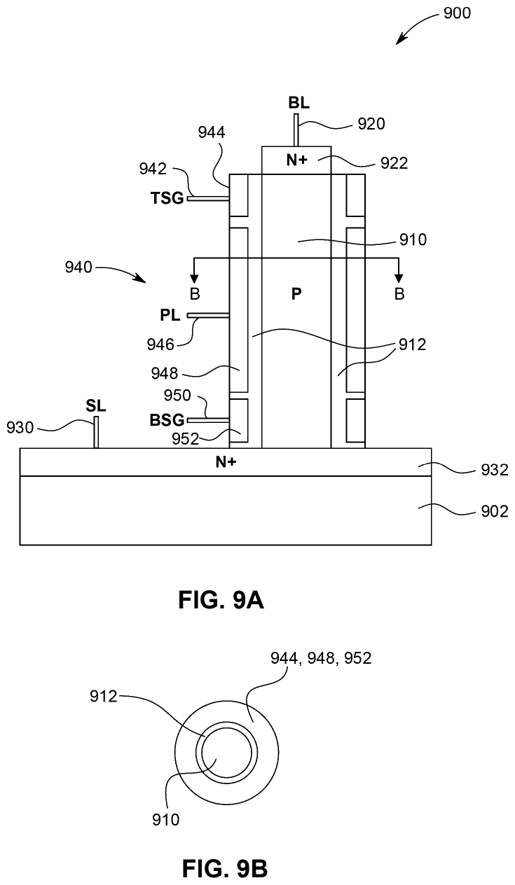

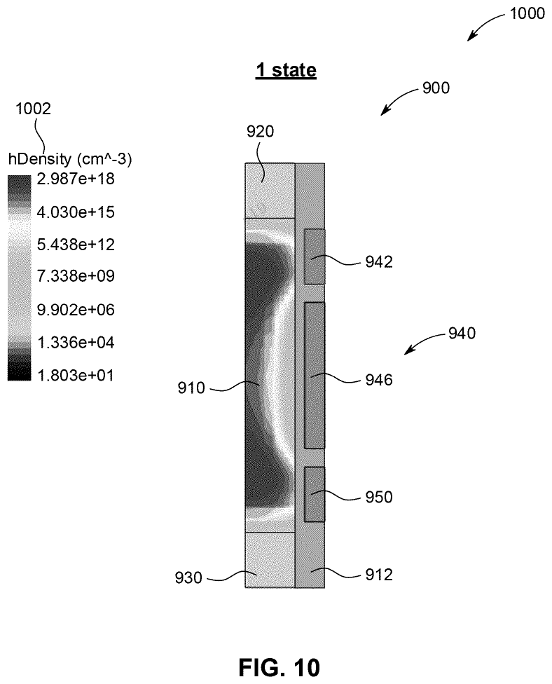

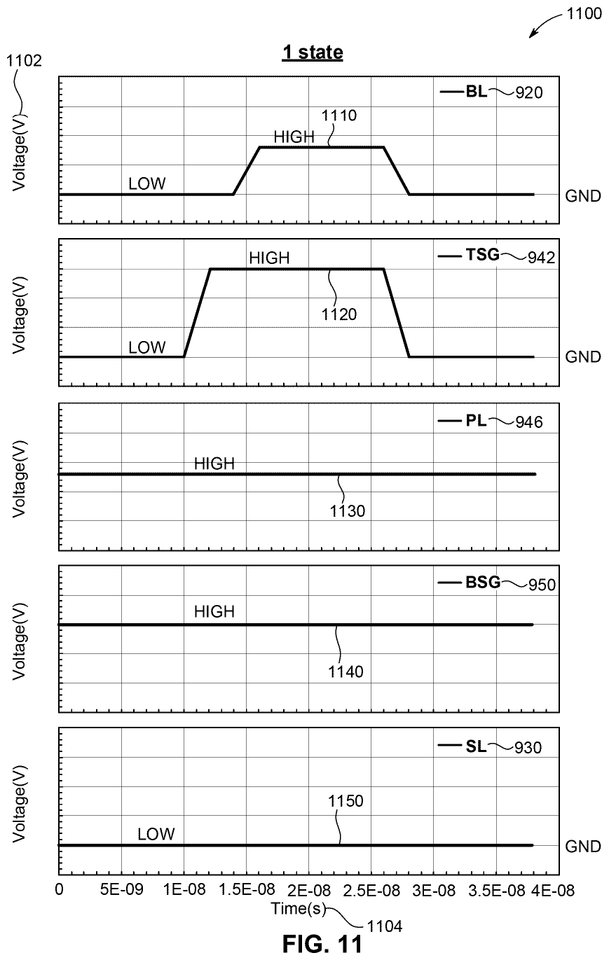

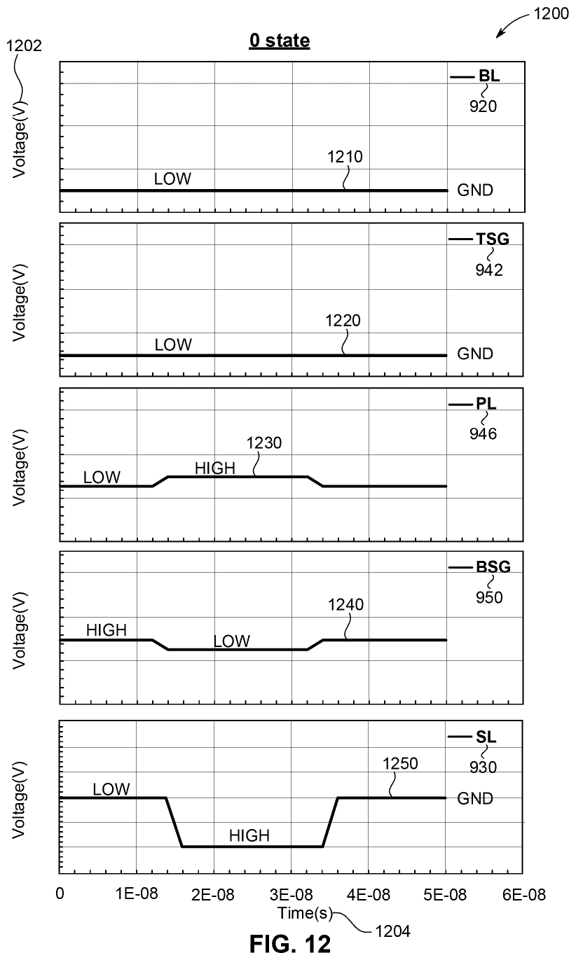

FIGS. 9A-12 illustrate tri-gate DFM device 900, according to exemplary aspects. FIGS. 9A and 9B are schematic cross-sectional illustrations of tri-gate DFM device 900, according to an exemplary aspect. FIG. 10 is a schematic cross-sectional illustration of charge density distribution 1000 of tri-gate DFM device 900 shown in FIG. 9A for a program state (1 state), according to an exemplary aspect. FIG. 11 is a schematic illustration of voltage distribution 1100 in tri-gate DFM device 900 shown in FIG. 9A for the program state (1 state) shown in FIG. 10, according to an exemplary aspect. FIG. 12 is a schematic illustration of voltage distribution 1200 in tri-gate DFM device 900 shown in FIG. 9A for an erase state (0 state), according to an exemplary aspect.

Tri-gate DFM device 900 can be configured to operate as a volatile capacitor-free dynamic random-access 3D memory device. Tri-gate DFM device 900 can be further configured to increase memory storage efficiency. Tri-gate DFM device 900 can be further configured to provide tri-gate control and different programming options (e.g., impact ionization, GIDL, GISL). Tri-gate DFM device 900 can be further configured to increase read, program, and erase operation rates. Tri-gate DFM device 900 can be further configured to decrease leakage current, decrease junction current, and decrease power consumption. Tri-gate DFM device 900 can be further configured to increase charge retention times (e.g., greater than 100 ms at 85° C. operating temperature) and decrease refresh rates (e.g., less than 10 Hz).

Tri-gate DFM device 900 can be further configured to provide faster operation speeds and higher density than DRAM or other types of volatile memory. Tri-gate DFM device 900 can be further configured to provide block refresh and block erase operations similar to flash memory functionality. Although tri-gate DFM device 900 is shown in FIGS. 9A-12 as a stand-alone apparatus and/or system, the aspects of this disclosure can be used with other apparatuses, systems, and/or methods, such as, but not limited to, 3D memory device 100, dual gate SGT device 200, DFM device 300, manufacturing method 1300, and/or flow diagram 1400.

As shown in FIG. 9A, tri-gate DFM device 900 can include substrate 902, pillar 910, dielectric 912, bit line (BL) 920, BL contact 922, source line (SL) 930, SL contact 932, and DFM cell 940. In some aspects, tri-gate DFM device 900 can be a vertical 3D memory device. In some aspects, tri-gate DFM device 900 can include one or more DFM devices (e.g., DFM device 300 shown in FIG. 3). In some aspects, tri-gate DFM device 900 can include one or more NAND DFM devices. In some aspects, tri-gate DFM device 900 can be part of a memory array, for example, memory array 160 of 3D memory device 100 shown in FIG. 1.

Substrate 902 can be configured to support pillar 910, dielectric 912, BL contact 922, SL contact 932, and DFM cell 940. Substrate 902 can be coupled to SL contact 932. In some aspects, substrate 902 can be a p-type semiconductor (e.g., p), for example, doped silicon. In some aspects, substrate 902 can include any planar wafer material, for example, Si, Ge, SiGe, GaAs, Group IV semiconductor, Group III-V semiconductor, Group II-VI semiconductor, graphene, sapphire, and/or any other semiconductor.

Pillar 910 can be configured to store electrical charge (e.g., holes). Pillar 910 can be between BL contact 922 and SL contact 932. In some aspects, pillar 910 can include a semiconductor material, for example, Si, doped Si, Ge, SiGe, GaAs, Group IV semiconductor, Group III-V semiconductor, Group II-VI semiconductor, graphene, sapphire, and/or any other semiconductor. In some aspects, pillar 910 can be doped (e.g., p-type). In some aspects, pillar 910 can have a doping concentration of about 1×10¹⁶ cm⁻³ to about 5×10¹⁸ cm⁻³. For example, pillar 910 can have a doping concentration of about 1×10¹⁸ cm⁻³. In some aspects, pillar 910 can have a diameter of about 1 nm to about 100 nm. For example, pillar 910 can have a diameter of about 50 nm. In some aspects, pillar 910 can be monolithic. For example, as shown in FIG. 9A, pillar 910 can be a single monolithic vertical pillar. In some aspects, pillar 910 can be formed from the same material as substrate 902.

Dielectric 912 can be configured to provide electrical insulation between pillar 910 and DFM cell 940. Dielectric 912 can surround pillar 910. In some aspects, dielectric 912 can include a dielectric material, for example, oxide, nitride, oxynitride, ceramic, glass, SOG, polymer, plastic, thermoplastic, resin, laminate, high-k dielectric, a combination thereof, and/or any other electrically insulating material. In some aspects, dielectric 912 can be a high-k dielectric configured to increase a gate capacitance and decrease a leakage current in pillar 910. In some aspects, dielectric 912 can have a radial thickness of about 1 nm to about 30 nm. For example, dielectric 912 can have a radial thickness of about 3 nm. In some aspects, dielectric 912 can be monolithic. For example, as shown in FIG. 9A, dielectric 912 can be a single monolithic vertical dielectric.

BL 920 can be configured to address pillar 910 in tri-gate DFM device 900. BL 920 can be further configured to flow electrical charge through DFM cell 940. BL 920 can be coupled to BL contact 922. BL contact 922 can be configured to act as a drain connection to pillar 910. BL contact 922 can be coupled to a top side of DFM cell 940. In some aspects, BL contact 922 can be n-type (e.g., n+) and pillar 910 can be p-type (e.g., p). In some aspects, BL contact 922 can include a conductive material, for example, a metal, a doped semiconductor, polysilicon, tungsten, and/or any other suitable conductor.

SL 930 can be configured to address pillar 910 in tri-gate DFM device 900. SL 930 can be further configured to flow electrical charge through DFM cell 940. SL 930 can be coupled to SL contact 932. SL contact 932 can be configured to act as a source connection to pillar 910. SL contact 932 can be coupled to a bottom side of DFM cell 940. In some aspects, SL contact 932 can be n-type (e.g., n+) and pillar 910 can be p-type (e.g., p). In some aspects, SL contact 932 can include a conductive material, for example, a metal, a doped semiconductor, polysilicon, tungsten, and/or any other suitable conductor. In some aspects, different voltage combinations applied to BL 920, SL 930, and DFM cell 940 can define read, program (write), and erase operations in tri-gate DFM device 900.

DFM cell 940 can be configured to read, program, and erase electrical charge on pillar 910. DFM cell 940 can be coupled to BL contact 922 and SL contact 932. DFM cell 940 can include top select gate line (TSG) 942, TSG contact 944, plate line (PL) 946, PL contact 948, bottom select gate line (BSG) 950, and BSG contact 952. In some aspects, DFM cell 940 can be configured for impact ionization programming, GIDL programming, or both.

TSG 942 can be configured to address pillar 910 in tri-gate DFM device 900. TSG 942 can be further configured to address and non-destructively read electrical charge on pillar 910. In some aspects, TSG 942 can be configured as a word line. TSG 942 can be coupled to TSG contact 944. TSG contact 944 can be configured to act as a first gate connection to pillar 910. TSG contact 944 can surround a first portion of dielectric 912 which surrounds a first portion of pillar 910 thereby forming a first concentric transistor in DFM cell 940. In some aspects, TSG contact 944 can include a conductive material (e.g., metal, polysilicon, tungsten, etc.). In some aspects, TSG 942 can provide voltage to TSG contact 944, thereby inducing an electric field within pillar 910, to read, program, or erase charge on pillar 910. In some aspects, as shown in FIG. 9A, TSG contact 944 can be between BL contact 922 and PL contact 948.

In some aspects, TSG 942 can increase a program (write) rate in DFM cell 940. For example, TSG 942 can increase charge flow to PL 946 thereby increasing the program (write) rate. In some aspects, TSG 942 can be configured to increase a program (write) rate in pillar 910. For example, for GIDL programming, TSG 942 can increase a charge flow from BL contact 922 to PL contact 948 thereby increasing the program (write) rate (e.g., a write rate greater than 100 MHz with less than 10 ns write time). In some aspects, TSG 942 can increase a charge flow in pillar 910. For example, the charge flow can have a charge density greater than about 1×10¹⁷ cm⁻³.

In some aspects, TSG 942 can be used for GIDL programming to create a charge (e.g., hole) barrier to provide selective programming (writing) in pillar 910. In some aspects, for GIDL programming, TSG 942 can be configured to create a charge barrier between BL contact 922 and PL contact 948 to selectively program pillar 910. For example, the charge barrier can have a charge density no greater than 1×10¹⁷ cm⁻³.

In some aspects, TSG 942 can provide charge separation between PL 946 and BL 920 thereby increasing charge retention times in pillar 910 and decreasing refresh rates in DFM cell 940. For example, TSG 942 can increase charge retention times to at least 100 ms at 85° C. operating temperature and decrease refresh rates to no greater than 10 Hz. In some aspects, TSG 942 can provide charge separation between PL 946 and BL 920 thereby decreasing junction leakage between pillar 910 and BL contact 922. In some aspects, TSG 942 can increase charge flow in pillar 910 thereby increasing a depletion area in pillar 910.

In some aspects, TSG 942 can decrease a program (write) time in tri-gate DFM device 900 to about 20 ns to about 1 ns. For example, the program (write) time can be about 5 ns. In some aspects, TSG 942 can increase a program (write) rate in tri-gate DFM device 900 to about 50 MHz to about 1 GHz. For example, the program (write) rate can be about 200 MHz.

In some aspects, TSG 942 can decrease a read time in tri-gate DFM device 900 to about 10 ns to about 100 ps. For example, the read time can be about 1 ns. In some aspects, TSG 942 can increase a read rate in tri-gate DFM device 900 to about 100 MHz to about 10 GHz. For example, the read rate can be about 1 GHz.

In some aspects, TSG 942 can decrease an erase time in tri-gate DFM device 900 to about 20 ns to about 1 ns. For example, the erase time can be about 5 ns. In some aspects, TSG 942 can increase an erase rate in tri-gate DFM device 900 to about 50 MHz to about 1 GHz. For example, the erase rate can be about 200 MHz.

PL 946 can be configured to address pillar 910 in tri-gate DFM device 900. PL 946 can be further configured to program (e.g., write) pillar 910. In some aspects, PL 946 can act as a traditional current-valve gate (e.g., similar to a MOSFET gate) for pillar 910 and cover a majority of a length of pillar 910. PL 946 can be coupled to PL contact 948. PL contact 948 can be configured to act as a second gate connection to pillar 910. PL contact 948 can surround a second portion of dielectric 912 which surrounds a second portion of pillar 910 thereby forming a second concentric transistor in DFM cell 940. In some aspects, PL contact 948 can include a conductive material (e.g., metal, polysilicon, tungsten, etc.). In some aspects, PL 946 can provide voltage to PL contact 948, thereby inducing an electric field within pillar 910, to read, program, or erase charge on pillar 910. In some aspects, DFM cell 940 can form a DFM device, for example, DFM device 300 shown in FIG. 3.

BSG 950 can be configured to address pillar 910 in tri-gate DFM device 900. BSG 950 can be further configured to address and non-destructively read electrical charge on pillar 910. In some aspects, BSG 950 can be configured as a word line. BSG 950 can be coupled to BSG contact 952. BSG contact 952 can be configured to act as a third gate connection to pillar 910. BSG contact 952 can surround a third portion of dielectric 912 which surrounds a third portion of pillar 910 thereby forming a third concentric transistor in DFM cell 940. In some aspects, BSG contact 952 can include a conductive material (e.g., metal, polysilicon, tungsten, etc.). In some aspects, BSG 950 can provide voltage to BSG contact 952, thereby inducing an electric field within pillar 910, to read, program, or erase charge on pillar 910. In some aspects, as shown in FIG. 9A, BSG contact 952 can be between SL contact 932 and PL contact 948. In some aspects, as shown in FIG. 9A, PL contact 948 can be between TSG contact 944 and BSG contact 952.

In some aspects, BSG 950 can increase a program (write) rate in DFM cell 940. For example, BSG 950 can increase charge flow to PL 946 thereby increasing the program (write) rate. In some aspects, BSG 950 can be configured to increase a program (write) rate in pillar 910. For example, for GISL programming, BSG 950 can increase a charge flow from SL contact 932 to PL contact 948 thereby increasing the program (write) rate (e.g., a write rate greater than 100 MHz with less than 10 ns write time). In some aspects, BSG 950 can increase a charge flow in pillar 910. For example, the charge flow can have a charge density greater than about 1×10¹⁷ cm⁻³.

In some aspects, BSG 950 can be used for GISL programming to create a charge (e.g., hole) barrier to provide selective programming (writing) in pillar 910. In some aspects, for GISL programming, BSG 950 can be configured to create a charge barrier between SL contact 932 and PL contact 948 to selectively program pillar 910. For example, the charge barrier can have a charge density no greater than 1×10¹⁷ cm⁻³.

In some aspects, BSG 950 can provide charge separation between PL 946 and SL 930 thereby increasing charge retention times in pillar 910 and decreasing refresh rates in DFM cell 940. For example, BSG 950 can increase charge retention times to at least 100 ms at 85° C. operating temperature and decrease refresh rates to no greater than 10 Hz. In some aspects, BSG 950 can provide charge separation between PL 946 and SL 930 thereby decreasing junction leakage between pillar 910 and SL contact 932. In some aspects, BSG 950 can increase charge flow in pillar 910 thereby increasing a depletion area in pillar 910.

In some aspects, BSG 950 can decrease a program (write) time in tri-gate DFM device 900 to about 20 ns to about 1 ns. For example, the program (write) time can be about 5 ns. In some aspects, BSG 950 can increase a program (write) rate in tri-gate DFM device 900 to about 50 MHz to about 1 GHz. For example, the program (write) rate can be about 200 MHz.

In some aspects, BSG 950 can decrease a read time in tri-gate DFM device 900 to about 10 ns to about 100 ps. For example, the read time can be about 1 ns. In some aspects, BSG 950 can increase a read rate in tri-gate DFM device 900 to about 100 MHz to about 10 GHz. For example, the read rate can be about 1 GHz.

In some aspects, BSG 950 can decrease an erase time in tri-gate DFM device 900 to about 20 ns to about 1 ns. For example, the erase time can be about 5 ns. In some aspects, BSG 950 can increase an erase rate in tri-gate DFM device 900 to about 50 MHz to about 1 GHz. For example, the erase rate can be about 200 MHz.

As shown in FIG. 10, charge density distribution 1000 shows charge (e.g., hole) density 1002 within tri-gate DFM device 900 for a first logic state (1 state) after 100 ms at an operating temperature of 85° C. In some aspects, as shown in FIG. 10, in the first logic state (1 state), pillar 910 of DFM cell 940 can include electrical charge (e.g., holes). Charge density distribution 1000 can include charge (e.g., hole) density 1002, which can range from about 1.8×10¹ cm⁻³ to about 3×10¹⁸ cm⁻³. The first logic state (1 state) represents a program (write) operation on tri-gate DFM device 900, whereby different voltage combinations applied to BL 920, SL 930, TSG 942, PL 946, and BSG 950 form charge (e.g., holes) on pillar 910 of tri-gate DFM device 900. In some aspects, as shown in FIG. 10, in the first logic state (1 state), a majority of pillar 910 retains charge of at least 1×10¹⁷ cm⁻³ after 100 ms at an operating temperature of 85° C. For example, a portion of pillar 910 adjacent PL contact 948 retains charge of at least 1×10¹⁷ cm⁻³.

As shown in FIG. 11, voltage distribution 1100 shows BL voltage waveform 1110, TSG voltage waveform 1120, PL voltage waveform 1130, BSG voltage waveform 1140, and SL voltage waveform 1150 within tri-gate DFM device 900 for the first logic state (1 state) after 100 ms at an operating temperature of 85° C. Voltage distribution 1100 shows voltage 1102 applied by BL 920, SL 930, TSG 942, PL 946, and BSG 950 to pillar 910 in tri-gate DFM device 900 over time 1104. In some aspects, as shown in FIG. 11, in the first logic state (1 state), BL contact 922 can apply a HIGH level voltage (e.g., about 0.8 V), TSG contact 944 can apply a HIGH level voltage (e.g., about 1.5 V), PL contact 948 can apply a HIGH level voltage (e.g., about 0.8 V), BSG contact 952 can apply a HIGH level voltage (e.g., about 1 V), and SL contact 932 can apply a LOW level voltage (e.g., about 0 V). In some aspects, as shown in FIGS. 10 and 11, voltage distribution 1100 applied to BL 920, SL 930, and DFM cell 940 can define first logic state (1 state) in tri-gate DFM device 900, for example, by storing charge (e.g. holes) on pillar 910.

As shown in FIG. 12, voltage distribution 1200 shows BL voltage waveform 1210, TSG voltage waveform 1220, PL voltage waveform 1230, BSG voltage waveform 1240, and SL voltage waveform 1250 within tri-gate DFM device 900 for a second logic state (0 state) after 100 ms at an operating temperature of 85° C. Voltage distribution 1200 shows voltage 1202 applied by BL 920, SL 930, TSG 942, PL 946, and BSG 950 to pillar 910 in tri-gate DFM device 900 over time 1204. In some aspects, as shown in FIG. 12, in the second logic state (0 state), BL contact 922 can apply a LOW level voltage (e.g., about 0 V or GND), TSG contact 944 can apply a LOW level voltage (e.g., about 0 V or GND), PL contact 948 can apply a HIGH level voltage (e.g., about 1 V), BSG contact 952 can apply a HIGH level voltage (e.g., about 0.8 V), and SL contact 932 can apply a HIGH level voltage (e.g., about −2 V). In some aspects, in the second logic state (0 state), SL contact 932 can apply a HIGH level voltage (e.g., about −1 V to about −5 V). In some aspects, as shown in FIG. 12, voltage distribution 1200 applied to BL 920, SL 930, and DFM cell 940 can define second logic state (0 state) in tri-gate DFM device 900, for example, by removing charge (e.g. holes) on pillar 910.

### Exemplary Manufacturing Method

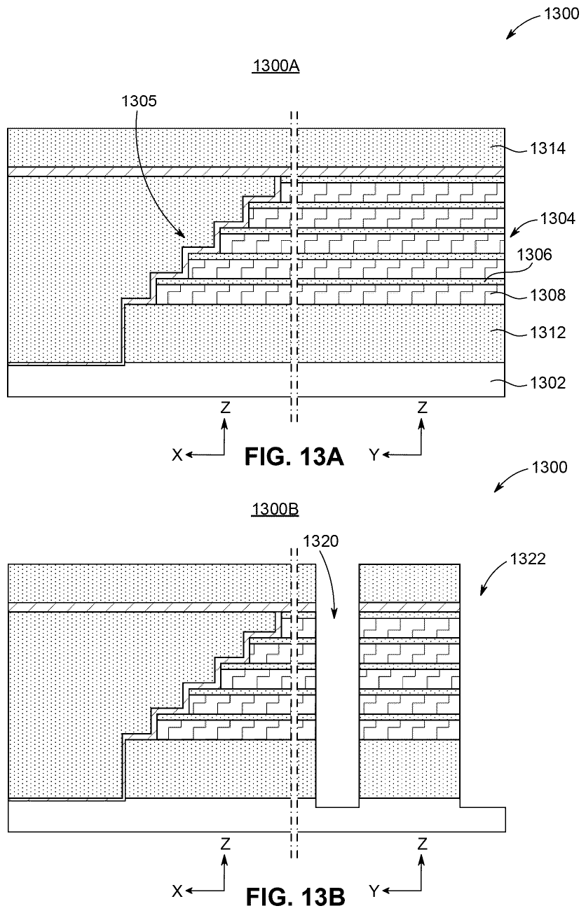

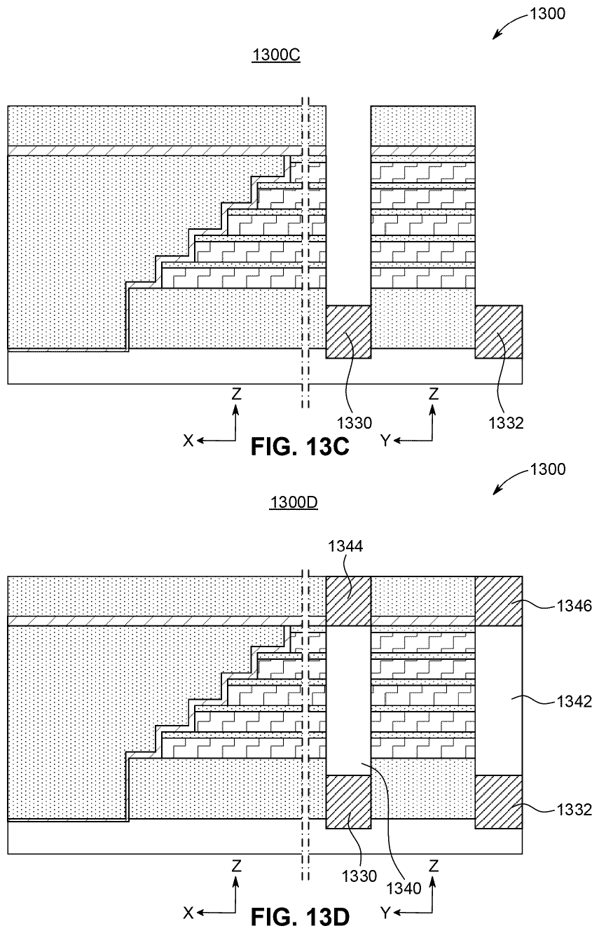

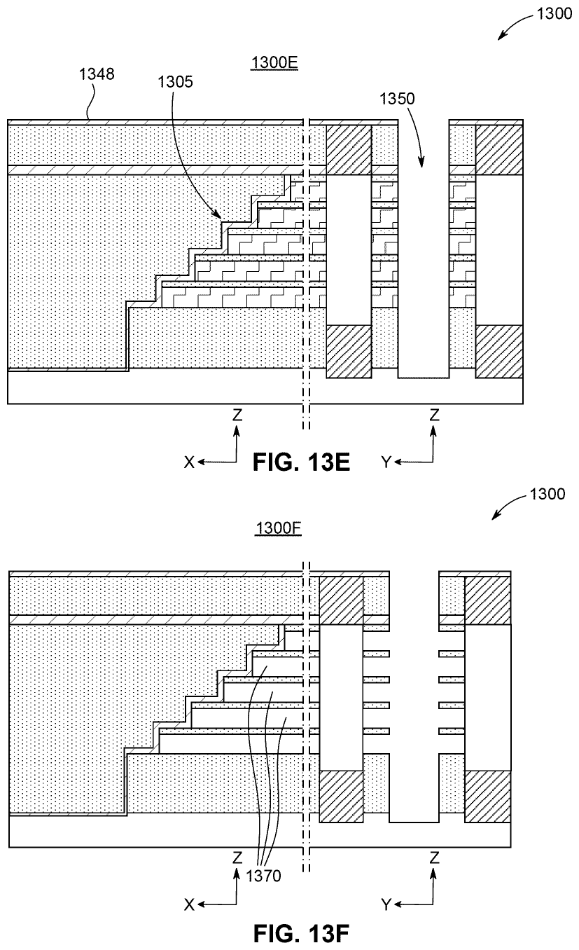

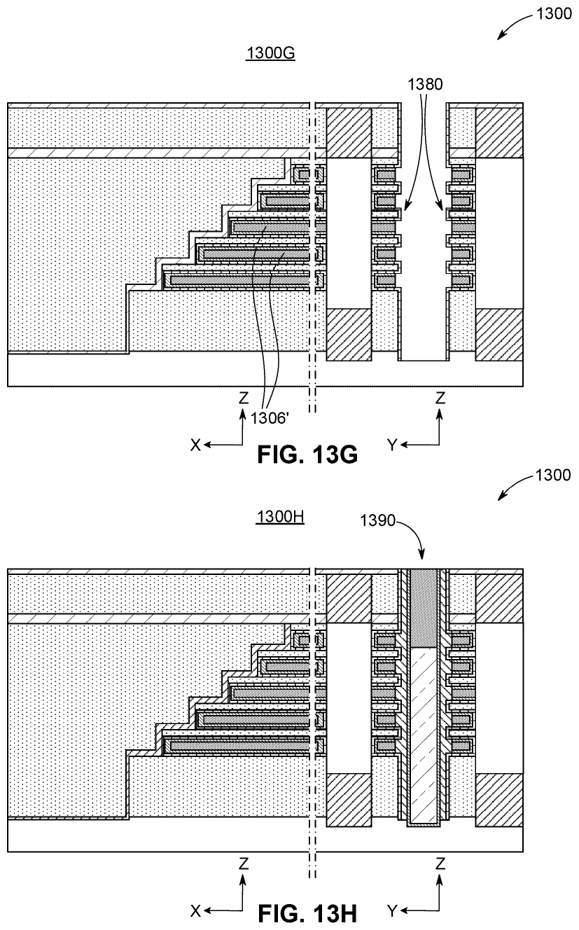

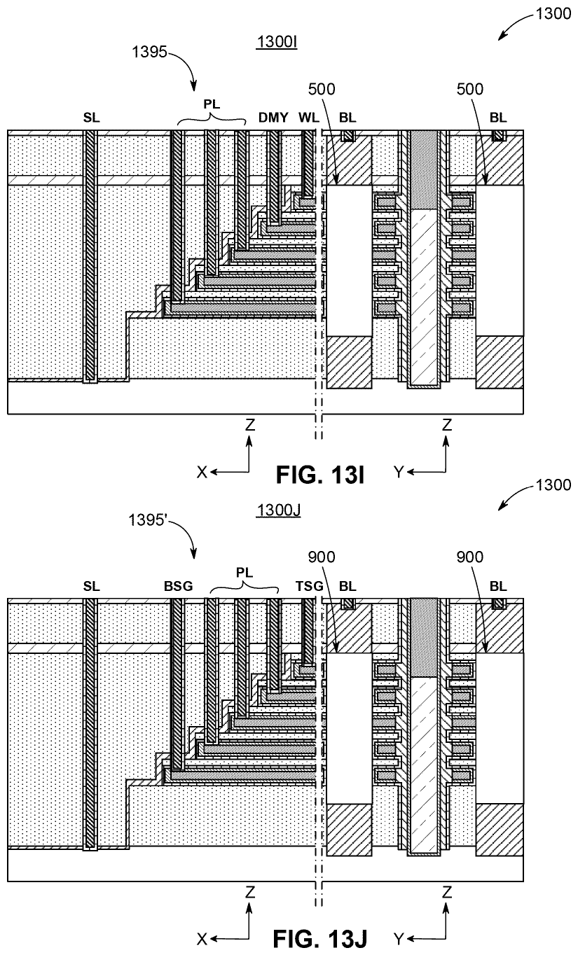

FIGS. 13A through 13J illustrate manufacturing method 1300 for forming tri-gate DFM device 500 shown in FIG. 5A and tri-gate DFM device 900 shown in FIG. 9A, according to exemplary aspects. It is to be appreciated that not all steps in FIGS. 13A through 13J are needed to perform the disclosure provided herein. Further, some of the steps may be performed simultaneously, sequentially, and/or in a different order than shown in FIGS. 13A through 13J. Manufacturing method 1300 shall be described with reference to FIGS. 13A through 13J. However, manufacturing method 1300 is not limited to those example aspects.

In step 1300A, as shown in the example of FIG. 13A, stack 1304 with staircase structure 1305 including first dielectric layer 1306 (e.g., silicon oxide), second dielectric layer 1308 (e.g., silicon nitride), bottom isolation layer 1312, and top isolation layer 1314 are formed as an alternating dielectric stack atop substrate 1302.

In step 1300B, as shown in the example of FIG. 13B, first channel trench 1320 and second channel trench 1322 are formed in the alternating dielectric stack (e.g., stack 1304).

In some aspects, first and second channel trenches 1320, 1322 can be formed by etching in alternating dielectric stack, for example, anisotropic etching.

In step 1300C, as shown in the example of FIG. 13C, first bottom contact 1330 and second bottom contact 1332 are formed in first and second channel trenches 1320, 1322, respectively. In some aspects, forming first and second bottom contacts 1330, 1332 can include epitaxially growing first and second bottom contacts 1330, 1332, for example, by selective epitaxial growth (SEG).

In step 1300D, as shown in the example of FIG. 13D, first pillar 1340 and second pillar 1342 are formed atop first and second bottom contacts 1330, 1332, respectively, and first top contact 1344 and second top contact 1346 are formed atop first and second pillars 1340, 1342, respectively. In some aspects, forming first and second pillars 1340, 1342 can include epitaxially growing first and second pillars 1340, 1342 atop first and second bottom contacts 1330, 1332, for example, by SEG. In some aspects, forming first and second top contacts 1344, 1346 can include doping first and second pillars 1340, 1342 to form first and second top contacts 1344, 1346, for example, by ion implanting. In some aspects, first and second pillars 1340, 1342 can be configured to form first and second memory cells (e.g., DFM cell 540 shown in FIG. 5A, DFM cell 940 shown in FIG. 9A), where first memory cell (e.g., DFM cell 540 shown in FIG. 5A, DFM cell 940 shown in FIG. 9A) is coupled to first top contact 1344 and first bottom contact 1330, and second memory cell (e.g., DFM cell 540 shown in FIG. 5A, DFM cell 940 shown in FIG. 9A) is coupled to second top contact 1346 and second bottom contact 1332, respectively.

In step 1300E, as shown in the example of FIG. 13E, gate line trench 1350 is formed in the alternating dielectric stack (e.g., stack 1304). FIG. 13E shows a cross-sectional view of gate line trench 1250 along the YZ-plane and a separate (orthogonal) cross-sectional view of staircase structure 1205 along the XZ-plane.

In step 1300F, as shown in the example of FIG. 13F, second dielectric layer 1308 (e.g., silicon nitride) of stack 1304 is removed to form dielectric layer void 1370. In some aspects, second dielectric layer 1308 can be removed by etching from a lateral edge of stack 1304, for example, isotropic etching.

In step 1300G, as shown in the example of FIGS. 13F and 13G, high-k metal gate HKMG) stack 1380 is formed with conductive layers 1306′ in dielectric layer void 1370.

In step 1300H, as shown in the example of FIGS. 13E and 13H, gate line slit (GLS) 1390 is formed in gate line trench 1350.

In step 1300I, as shown in the example of FIGS. 5A, 13C, 13D, and 13I, interconnects 1395 are formed to first and second top contacts 1344, 1346 (e.g., BL 520 shown in FIG. 5A), first and second pillars 1340, 1342 (e.g., DFM cell 540 shown in FIG. 5A), and first and second bottom contacts 1330, 1332 (e.g., SL 530 shown in FIG. 5A), respectively, to form one or more tri-gate DFM devices 500 shown in FIG. 5A. In some aspects, manufacturing method 1300 can include forming a DFM device, for example, tri-gate DFM device 500 shown in FIG. 5A. In some aspects, manufacturing method 1300 can include forming a NAND DFM device.

The aspects of interconnects 1395 shown in FIG. 13I and the aspects of interconnects 1395′ may be similar. Similar reference numbers are used to indicate features of the aspects of interconnects 1395 shown in FIG. 13I (e.g., to form tri-gate DFM device 500 shown in FIG. 5A) and the similar features of the aspects of interconnects 1395′ shown in FIG. 13J (e.g., to form tri-gate DFM device 900 shown in FIG. 9A). In some aspects, manufacturing method 1300 can include steps 1300A through 1300I to form one or more tri-gate DFM devices 500 shown in FIG. 5A. In some aspects, manufacturing method 1300 can include steps 1300A through 1300H and step 1300J, instead of step 13001, to form one or more tri-gate DFM devices 900 shown in FIG. 9A.

In step 1300J, as shown in the example of FIGS. 9A, 13C, 13D, and 13J, interconnects 1395′ are formed to first and second top contacts 1344, 1346 (e.g., BL 920 shown in FIG. 9A), first and second pillars 1340, 1342 (e.g., DFM cell 940 shown in FIG. 9A), and first and second bottom contacts 1330, 1332 (e.g., SL 930 shown in FIG. 9A), respectively, to form one or more tri-gate DFM devices 900 shown in FIG. 9A. In some aspects, manufacturing method 1300 can include forming a DFM device, for example, tri-gate DFM device 900 shown in FIG. 9A. In some aspects, manufacturing method 1300 can include forming a NAND DFM device.

### Exemplary Flow Diagram

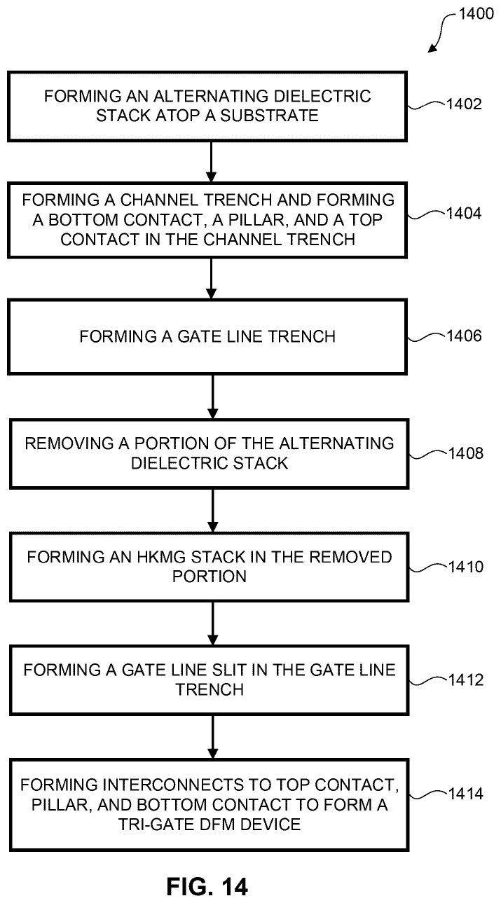

FIG. 14 illustrates flow diagram 1400 for forming tri-gate DFM device 500 shown in FIG. 5A and tri-gate DFM device 900 shown in FIG. 9A, according to exemplary aspects. It is to be appreciated that not all steps in FIG. 14 are needed to perform the disclosure provided herein. Further, some of the steps may be performed simultaneously, sequentially, and/or in a different order than shown in FIG. 14. Flow diagram 1400 shall be described with reference to FIGS. 5A, 9, and 13A through 13J. However, flow diagram 1400 is not limited to those example aspects.

In step 1402, as shown in the example of FIG. 13A, stack 1304 with staircase structure 1305 including first dielectric layer 1306 (e.g., silicon oxide), second dielectric layer 1308 (e.g., silicon nitride), bottom isolation layer 1312, and top isolation layer 1314 are formed as an alternating dielectric stack atop substrate 1302.

In step 1404, as shown in the example of FIGS. 13B-13D, first channel trench 1320 and second channel trench 1322 are formed in the alternating dielectric stack (e.g., stack 1304). In some aspects, first and second channel trenches 1320, 1322 can be formed by etching in alternating dielectric stack, for example, anisotropic etching. Further, first bottom contact 1330 and second bottom contact 1332 are formed in first and second channel trenches 1320, 1322, respectively. In some aspects, forming first and second bottom contacts 1330, 1332 can include epitaxially growing first and second bottom contacts 1330, 1332, for example, by SEG. Further, first pillar 1340 and second pillar 1342 are formed atop first and second bottom contacts 1330, 1332, respectively, and first top contact 1344 and second top contact 1346 are formed atop first and second pillars 1340, 1342, respectively. In some aspects, forming first and second pillars 1340, 1342 can include epitaxially growing first and second pillars 1340, 1342 atop first and second bottom contacts 1330, 1332, for example, by SEG. In some aspects, forming first and second top contacts 1344, 1346 can include doping first and second pillars 1340, 1342 to form first and second top contacts 1344, 1346, for example, by ion implanting.

In some aspects, first and second pillars 1340, 1342 can be configured to form first and second memory cells (e.g., DFM cell 540 shown in FIG. 5A, DFM cell 940 shown in FIG. 9A), where first memory cell (e.g., DFM cell 540 shown in FIG. 5A, DFM cell 940 shown in FIG. 9A) is coupled to first top contact 1344 and first bottom contact 1330, and second memory cell (e.g., DFM cell 540 shown in FIG. 5A, DFM cell 940 shown in FIG. 9A) is coupled to second top contact 1346 and second bottom contact 1332, respectively.

In step 1406, as shown in the example of FIG. 13E, gate line trench 1350 is formed in the alternating dielectric stack (e.g., stack 1304).

In step 1408, as shown in the example of FIG. 13F, second dielectric layer 1308 (e.g., silicon nitride) of stack 1304 is removed to form dielectric layer void 1370. In some aspects, second dielectric layer 1308 can be removed by etching from a lateral edge of stack 1304, for example, isotropic etching.

In step 1410, as shown in the example of FIGS. 13F and 13G, HKMG stack 1380 is formed with conductive layers 1306′ in dielectric layer void 1370.

In step 1412, as shown in the example of FIG. 13H, GLS 1390 is formed in gate line trench 1350.

In step 1414, as shown in the example of FIGS. 5A, 9, 13I, and 13J, interconnects 1395, 1395′ are formed to first and second top contacts 1344, 1346 (e.g., BL 520 shown in FIG. 5A, BL 920 shown in FIG. 9A), first and second pillars 1340, 1342 (e.g., DFM cell 540 shown in FIG. 5A, DFM cell 940 shown in FIG. 9A), and first and second bottom contacts 1330, 1332 (e.g., SL 530 shown in FIG. 5A, SL 930 shown in FIG. 9A), respectively, to form one or more tri-gate DFM devices 500 shown in FIG. 5A (e.g., interconnects 1395) or one or more tri-gate DFM devices 900 shown in FIG. 9A (e.g., interconnects 1395′). In some aspects, flow diagram 1400 can include forming a DFM device, for example, tri-gate DFM device 500 shown in FIG. 5A. In some aspects, flow diagram 1400 can include forming a DFM device, for example, tri-gate DFM device 900 shown in FIG. 9A. In some aspects, flow diagram 1400 can include forming a NAND DFM device.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself may be patterned and materials added on top of it may also be patterned, or may remain without patterning.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary aspects as contemplated by the inventor(s), and thus, are not intended to limit the aspects and the appended claims in any way.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

What is claimed is:

1. A three-dimensional memory device comprising:
a memory cell comprising:
a pillar configured to store an electrical charge;
an insulating layer surrounding the pillar;
a first gate contact surrounding a first portion of the insulating layer, the first gate contact coupled to a word line configured to address and non-destructively read the pillar;
a second gate contact surrounding a second portion of the insulating layer, the second gate contact coupled to a plate line configured to program the pillar; and
a third gate contact surrounding a third portion of the insulating layer, the third gate contact configured to control electrical charge conduction between the first gate contact and the second gate contact;
a top contact coupled to the memory cell, the top contact coupled to a bit line configured to flow electrical charge through the memory cell; and
a bottom contact coupled to the memory cell, the bottom contact coupled to a source line configured to flow electrical charge through the memory cell.

2. The memory device of claim 1, wherein the third gate contact is configured to increase a program rate of the pillar.

3. The memory device of claim 1, wherein the three-dimensional memory device is configured for impact ionization programming, gate-induced drain leakage (GIDL) programming, or both.

4. The memory device of claim 1, wherein the third gate contact is coupled to a dummy line.

5. The memory device of claim 4, wherein, for impact ionization programming, the dummy line applies a voltage to increase a charge flow from the first gate contact to the second gate contact.

6. The memory device of claim 1, wherein the third gate contact is coupled to a top select gate (TSG) line or a bottom select gate (BSG) line.

7. The memory device of claim 6, wherein, for GIDL programming, the TSG line or the BSG line applies a voltage to create a charge barrier between the first gate contact and the second gate contact to selectively program the pillar.

8. The memory device of claim 1, wherein the third gate contact is between the first gate contact and the second gate contact.

9. A three-dimensional memory device comprising:
a memory cell comprising:
a pillar configured to store an electrical charge;
an insulating layer surrounding the pillar;
a first gate contact surrounding a first portion of the insulating layer, the first gate contact coupled to a top select gate (TSG) line configured to address and non-destructively read the pillar;
a second gate contact surrounding a second portion of the insulating layer, the second gate contact coupled to a plate line configured to program the pillar; and
a third gate contact surrounding a third portion of the insulating layer, the third gate contact coupled to a bottom select gate (BSG) line configured to increase charge retention in the pillar;
a top contact coupled to the memory cell, the top contact coupled to a bit line configured to flow electrical charge through the memory cell; and
a bottom contact coupled to the memory cell, the bottom contact coupled to a source line configured to flow electrical charge through the memory cell.

10. The memory device of claim 9, wherein the second gate contact is between the first gate contact and the third gate contact.

11. The memory device of claim 9, wherein, in a first configuration, the top contact has a HIGH level voltage, the first gate contact has a HIGH level voltage, the second gate contact has a HIGH level voltage, the third gate contact has a HIGH level voltage, the bottom contact has a LOW level voltage, and the memory cell comprises the electrical charge.

12. The memory device of claim 11, wherein, in the first configuration, the third gate contact applies the HIGH level voltage to increase a depletion area of the pillar.

13. The memory device of claim 11, wherein, in the first configuration, the third gate contact applies the HIGH level voltage to increase a retention rate of the pillar and decrease a refresh rate of the memory cell.

14. The memory device of claim 9, wherein, in a second configuration, the top contact has a LOW level voltage, the first gate contact has a LOW level voltage, the second gate contact has a HIGH level voltage, the third gate contact has a HIGH level voltage, the bottom contact has a HIGH level voltage, and the memory cell comprises substantially no electrical charge.

15. The memory device of claim 9, wherein the three-dimensional memory device comprises a dynamic flash memory (DFM) device.

16. A method for forming a three-dimensional memory device, the method comprising:
forming an alternating dielectric stack atop a substrate;
forming a channel trench in the alternating dielectric stack;
forming a bottom contact in the channel trench;
forming a pillar atop the bottom contact;
forming a top contact atop the pillar;
forming a gate line trench in the alternating dielectric stack;
removing a portion of the alternating dielectric stack;
forming a high-k dielectric and conductive gate stack in the removed portion of the alternating dielectric stack to form a memory cell, wherein the memory cell comprises a first gate contact, a second gate contact, and a third gate contact;
forming a gate line slit in the gate line trench; and
forming interconnects to the top contact, the first gate contact, the second gate contact, the third gate contact, and the bottom contact.

17. The method of claim 16, wherein:
the first gate contact is coupled to a word line configured to address and non-destructively read the pillar,
the second gate contact is coupled to a plate line configured to program the pillar,
the third gate contact is coupled to a dummy line configured to increase a charge flow from the first gate contact to the second gate contact, and
the third gate contact is between the first gate contact and the second gate contact.

18. The method of claim 16, wherein:
the first gate contact is coupled to a word line configured to address and non-destructively read the pillar,
the second gate contact is coupled to a plate line configured to program the pillar,
the third gate contact is coupled to a top select gate (TSG) line configured to create a charge barrier between the first gate contact and the second gate contact to selectively program the pillar, and
the third gate contact is between the first gate contact and the second gate contact.

19. The method of claim 16, wherein:
the first gate contact is coupled to a top select gate (TSG) line configured to address and non-destructively read the pillar,
the second gate contact is coupled to a plate line configured to program the pillar,
the third gate contact is coupled to a bottom select gate (BSG) line configured to increase charge retention in the pillar, and
the second gate contact is between the first gate contact and the third gate contact.

20. The method of claim 16, wherein the method comprises forming a dynamic flash memory (DFM) device.
